(19) United States
(12) Patent Application Publication
(10) Pub. No.: US 2026/0308403 A1
(43) Pub. Date: Oct. 8, 2026

(54) INK COMPOSITION, ELECTRONIC DEVICE AND METHOD FOR MANUFACTURING THE SAME

(71) Applicant: Samsung Display Co., Ltd., Yongin-si (KR)

(72) Inventors: KYUWON CHO, Yongin-si (KR); YUN-HEE PARK, Yongin-si (KR); YISEOP SHIM, Yongin-si (KR); HYUNSEUNG LEE, Yongin-si (KR)

(21) Appl. No.: 19/370,467

(22) Filed: Oct. 27, 2025

(30) Foreign Application Priority Data
Apr. 4, 2025 (KR) 10-2025-0044307

(51) Int. Cl. C09D 11/107; C09D 11/037; H10H 29/01; H10H 29/855; H10K 59/12; H10K 59/126; H10K 59/80; H10K 102/00

(52) U.S. Cl. CPC C09D 11/107; C09D 11/037; H10H 29/0363; H10H 29/8552; H10K 59/1201; H10K 59/126; H10K 59/8792; H10K 2102/351

(57) ABSTRACT

An ink composition may include a first mill base, a base resin, a pigment, and a photo initiator. The first mill base may include a carbon nanotube having an average aspect ratio of about 2000 to about 5000, a first dispersant, and at least one first (meth)acrylate monomer. The ink composition may have excellent or suitable dispersion, storage stability, and processability.

### CROSS-REFERENCE TO RELATED APPLICATION

The present application claims priority to and the benefit of Korean Patent Application No. 10-2025-0044307, filed on Apr. 4, 2025, in the Korean Intellectual Property Office, the entire disclosure of which is incorporated herein by reference.

### BACKGROUND

### 1. Field

One or more embodiments of the present disclosure relate to an ink composition, an electronic device, and a method for manufacturing the electronic device. For example, one or more embodiments of the present disclosure relate to an ink composition for forming (to form) a light-shielding layer, an electronic device including the light-shielding layer, and a method for manufacturing the electronic device.

### 2. Description of the Related Art

Various display devices utilized in multimedia devices, such as televisions, mobile phones, tablet computers, and/or game consoles, are being developed. These display devices may be rigid or flexible, with the latter being bendable, foldable, or rollable.

To improve or enhance display quality, components (members) that reduce external light reflection are often employed. However, when developing such components, it is necessary or desired to provide sufficient or suitable optical properties for absorbing external light while also ensuring excellent or suitable durability and reliability under various usage conditions.

### SUMMARY

One or more aspects of embodiments of the present disclosure are directed toward an ink composition with improved or enhanced dispersion, storage stability, and processability.

One or more aspects of embodiments of the present disclosure are directed toward an electronic device including a light-shielding layer having excellent or suitable light-shielding properties, durability, and adhesion.

One or more aspects of embodiments of the present disclosure are directed toward a method for manufacturing an electronic device with improved or enhanced reliability and processability.

Additional aspects of embodiments will be set forth in part in the description which follows and, in part, will be apparent from the description or may be learned by practice of the presented embodiments of the disclosure.

One or more embodiments of the present disclosure provide an ink composition including a first mill base, a base resin, a pigment, and a photo initiator, wherein the first mill base includes a carbon nanotube having an average aspect ratio of about 2000 to about 5000, a first dispersant, and at least one first (meth)acrylate monomer.

In one or more embodiments, the carbon nanotube may have an average diameter of about 2 nm or less and an average length in a range of about 5 μm to about 10 μm.

In one or more embodiments, the carbon nanotube may include at least one of a single-walled carbon nanotube or a multi-walled carbon nanotube.

In one or more embodiments, with respect to the total weight (e.g., based on a total of 100 wt %) of the first mill base, the carbon nanotube may have a content (e.g., amount) in a range of about 5 wt % to about 20 wt %, the first dispersant may have a content (e.g., amount) in a range of about 1 wt % to about 10 wt %, and the at least one first (meth)acrylate monomer may have a content (e.g., amount) in a range of about 70 wt % to about 85 wt %.

In one or more embodiments, the pigment may include black pigment. The black pigment may include at least one of carbon black, lactam black, aniline black, or perylene black.

In one or more embodiments, the ink composition may further include a photopolymerization monomer (e.g., a photo polymerizable monomer) including two or more polymerizable residues (e.g., two or more polymerizable functional groups), a coupling agent, and an additive including at least one of an antistatic agent, a leveling agent, or a defoaming agent.

In one or more embodiments, the ink composition may further include a second mill base including the pigment, a second dispersant, and at least one second (meth)acrylate monomer.

In one or more embodiments, with respect to the total weight (e.g., based on a total of 100 wt %) of the ink composition, the base resin may have a content (e.g., amount) in a range of about 25 wt % to about 60 wt %, the photo initiator may have a content (e.g., amount) in a range of about 5 wt % to about 15 wt %, the first mill base may have a content (e.g., amount) in a range of about 1 wt % to about 15 wt %, the photopolymerization monomer may have a content (e.g., amount) in a range of about 25 wt % to about 60 wt %, the second mill base may have a content (e.g., amount) in a range of about 5 wt % to about 20 wt %, the coupling agent may have a content (e.g., amount) in a range of about 0.5 wt % to about 3 wt %, and the additive may have a content (e.g., amount) in a range of about 0.2 wt % to about 4 wt %.

In one or more embodiments, the ink composition may not include (e.g., may exclude) a solvent. For example, the ink composition is substantially free of added solvent, except for residual amounts present as impurities or by-products.

In one or more embodiments, the base resin may be a polymer resin having a weight average molecular weight in a range of about 5000 g/mol to about 50000 g/mol.

In one or more embodiments of the present disclosure, an electronic device includes a display module, a light-shielding layer arranged under the display module and formed or composed of an ink composition, and a housing that accommodates the display module.

In one or more embodiments, the light-shielding layer may have a thickness in a range of about 9 μm to about 16 μm.

In one or more embodiments, the display module may include a base layer, and a display element layer arranged on the base layer and including a light-emitting element, and the light-shielding layer may be directly under the base layer.

In one or more embodiments, the light-shielding layer may be a single layer formed through the ink composition.

In one or more embodiments of the present disclosure, a method for manufacturing an electronic device includes providing a display module, and forming a light-shielding layer by providing an ink composition on a rear surface of the display module.

In one or more embodiments, the method for manufacturing an electronic device may further include preparing the ink composition, wherein the preparing of the ink composition may include preparing a first mill base composition by mixing a carbon nanotube having an average aspect ratio of about 2000 to about 5000, a first dispersant, and at least one first (meth)acrylate monomer.

In one or more embodiments, the forming of the light-shielding layer may include forming a preliminary light-shielding layer by providing the ink composition on the rear surface of the display module, and photocuring the preliminary light-shielding layer.

In one or more embodiments, the providing of the ink composition may be performed in a screen printing method.

In one or more embodiments, the display module may include a base layer, and a display element layer arranged on the base layer and including a light-emitting element, and the light-shielding layer may be directly under a base layer.

In one or more embodiments, the base layer may include a glass substrate, the method for manufacturing an electronic device may further include etching a lower surface of the base layer spaced and/or apart (e.g., spaced apart or separated) from the display element layer, before the forming of the light-shielding layer, and in the forming of the light-shielding layer, the ink composition may be applied on the etched lower surface of the base layer.

For example, one or more embodiments of the present disclosure provide an integrated technical solution that addresses the need for an ink composition capable of forming a light-shielding layer with superior optical performance, mechanical durability, and adhesion, while maintaining excellent or suitable dispersion stability and processability during manufacturing. By incorporating a carbon nanotube-based mill base, specific dispersants, and (meth)acrylate monomers in defined proportions, the disclosed ink composition achieves enhanced light absorption and structural integrity without the need of solvents. Furthermore, the disclosed electronic device and manufacturing method leverage these material properties to produce display modules with improved or enhanced reliability, reduced external light reflection, and compatibility with scalable processes, such as screen printing and photocuring. These features collectively enable the development of display devices that deliver the desired performance and durability characteristics.

### BRIEF DESCRIPTION OF THE DRAWINGS

The accompanying drawings are included to provide a further understanding of embodiments of the subject matter of the present disclosure and are incorporated in and constitute a part of this specification. The drawings illustrate embodiments of the subject matter of the present disclosure and, together with the description, serve to explain principles of embodiments of the subject matter of the present disclosure. In the drawings:

FIG. 1 is a perspective view illustrating an electronic device according to one or more embodiments of the present disclosure;

FIG. 2 is an exploded perspective view of an electronic device according to one or more embodiments of the present disclosure;

FIG. 3A is a block diagram of an electronic device according to one or more embodiments of the present disclosure;

FIG. 3B is schematic diagrams of electronic devices according to one or more embodiments of the present disclosure;

FIG. 3C is a diagram illustrating an inside of a vehicle in which electronic devices according to one or more embodiments of the present disclosure are arranged;

FIG. 4 is a cross-sectional view of a display device according to one or more embodiments of the present disclosure;

FIG. 5 is a partially enlarged cross-sectional view of a display device according to one or more embodiments of the present disclosure;

FIG. 6 is a flowchart illustrating a method for manufacturing an electronic device according to one or more embodiments of the present disclosure;

FIGS. 7A-7K are cross-sectional views illustrating one or more operations of a method for manufacturing an electronic device according to one or more embodiments of the present disclosure;

FIG. 8 is a diagram illustrating a limitation generated in screen printing utilizing an ink composition according to Comparative Example;

FIG. 9 is a diagram illustrating a method to evaluate flowability of an ink composition; and

FIGS. 10A and 10B are diagrams illustrating a method to evaluate a smearing distance of a light-shielding layer.

### DETAILED DESCRIPTION

The subject matter of the present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure. The drawings and description are to be regarded as illustrative in nature and not restrictive. Like reference numerals designate like elements throughout the attached drawings and the written description, and duplicative descriptions thereof may not be provided in the specification.

The utilization of “may” if (e.g., when) describing embodiments of the present disclosure refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

As used herein, the singular forms “a,” “an,” and “the” are intended to include the plural forms as well, unless the context clearly indicates otherwise. The singular expression includes the plural expression unless the context clearly dictates otherwise.

As used herein, the term “and/or” or “or” includes any and all combinations of one or more of the associated listed items.

Throughout the present disclosure, the expressions, such as “at least one of,” “one of,” and “selected from,” if (e.g., when) preceding a list of elements, modify the entire list of elements and do not modify the individual elements of the list. For example, “at least one of a, b, or c,” “at least one selected from among a, b, and c,” “at least one selected from among a to c,” and/or the like indicates only a, only b, only c, both (e.g., simultaneously) a and b, both (e.g., simultaneously) a and c, both (e.g., simultaneously) b and c, all of a, b, and c, or variations thereof.

As used herein, “combination thereof” may refer to a mixture, a stack, a composite, a copolymer, an alloy, a blend, a reaction product, and/or the like of constituents.

In the present disclosure, if (e.g., when) a component (or a region, a layer, a portion, and/or the like) is referred to as being “on,” “connected to,” or “coupled to” another component, it refers to that it is placed/connected/coupled directly on the other component or a third component may be arranged between them. In contrast, if (e.g., when) a component is referred to as being “directly on,” “directly connected to,” or “directly coupled to” another component, there are no intervening components present therebetween.

In the drawings, the thickness of layers, films, panels, regions, and/or the like may be exaggerated for clarity. In the drawings, the thickness of a part of layers, regions, and/or the like may be exaggerated for better understanding and ease of description.

The terms, such as “first,” “second,” and/or the like, may be used to describe one or more suitable components, but the components should not be limited by the terms. These terms are only used for the purpose of distinguishing one component from other components. For example, without departing from the scope of the present disclosure, a first component may be referred to as a second component, and similarly, a second component may be referred to as a first component.

The terms, such as “below,” “lower,” “above,” and “upper,” are used to describe the relationship between the components illustrated in the drawings. The terms are relative concepts and are described based on the directions indicated in the drawings.

The terms, such as “includes,” “has,” “including,” and “having,” are intended to designate the presence of a feature, number, step (e.g., act or task), action, component, part, or combination thereof as described in the specification, and it should be understood that it does not preclude the possibility of presence or addition of one or more other features, numbers, steps, operations, components, parts, or combinations thereof. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within ±30%, ±20%, ±10%, or ±5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

In the present disclosure, “directly arranged” may refer to that there is no layer, film, region, plate, and/or the like added between a portion, such as a layer, a film, a region, or a plate, and another portion. For example, “direct arranged” may refer to placing two layers or two members without using an additional member, such as an adhesive member therebetween.

Unless otherwise defined, all terms (including technical and scientific terms) used in the present disclosure have substantially the same meaning as generally understood by one of ordinary skill in the art to which the present disclosure belongs. Also, the terms defined in generally used dictionaries should be interpreted as having a meaning consistent with the meaning having in the context of the related technology and should not be interpreted as too ideal or too formal unless explicitly defined here.

In the present disclosure, a monomer according to the present disclosure is distinguished from an oligomer and a polymer and refers to a compound having a weight average molecular weight in a range of about 1000 g/mol or less. In the present disclosure, “a photopolymerization functional group” may refer to a group involved in a polymerization reaction, for example, a double bond, a (meth)acrylate group, an epoxy group, and/or the like.

In the present disclosure, “(meth)acrylate” refers to acrylate and methacrylate, “(meth)acryl refers to acryl and methacryl, and “(meth)acryloyl refers to acryloyl and methacryloyl.

Hereinafter, an electronic device according to one or more embodiments of the present disclosure will be described in more detail with reference to the drawings.

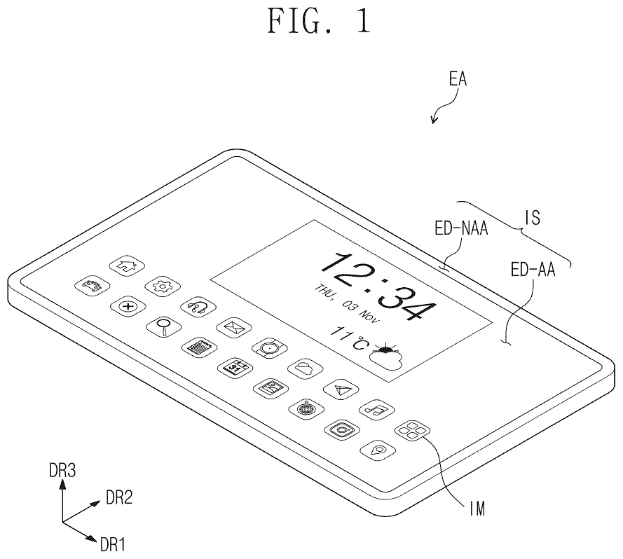

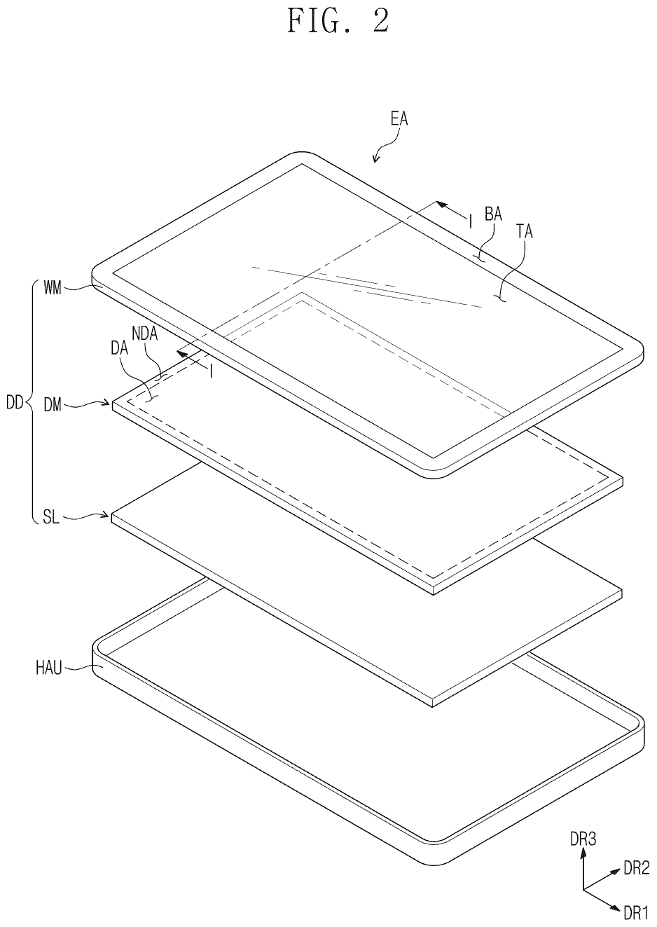

FIG. 1 is a perspective view illustrating an electronic device according to one or more embodiments of the present disclosure. FIG. 2 is an exploded perspective view of an electronic device according to one or more embodiments of the present disclosure.

An electronic device EA according to one or more embodiments of the present disclosure may be a display device activated in response to an electrical signal and displaying an image. The electronic device EA may include one or more suitable embodiments. For example, the electronic device EA may include not only large devices, such as a television and/or an external billboard, but also small devices and medium devices, such as a monitor, a mobile phone, a tablet computer, a navigation system, and/or a game console. Also, the embodiments of the electronic device EA are examples and should not be limited to any one as long as they do not depart from the scope of the present disclosure. For example, these examples are illustrative and not limiting, as one or more embodiments of the present disclosure apply to any suitable display device/electronic device within the scope of the present disclosure.

In FIG. 1 and the following drawings, a first direction DR1 to a third direction DR3 are illustrated in FIG. 1 and the consecutive drawings, and directions indicated by the first to third directions DR1, DR2, and DR3 as described in the present disclosure are relative concepts and may thus be changed into other directions.

In the present disclosure, a thickness direction of the electronic device EA may be a direction parallel to the third direction DR3, which is a normal direction of a plane defined by the first direction DR1 and the second direction DR2. In the present disclosure, front surfaces (or upper surfaces) and rear surfaces (or lower surfaces) of members that constitute the electronic device EA may be defined with respect to the third direction DR3.

The electronic device EA may be to display an image IM in the third direction DR3 through a display surface IS parallel to a surface defined by the first direction DR1 and the second direction DR2. The third direction DR3 may be parallel to a normal direction of the display surface IS. The display surface IS on which the image IM is displayed may correspond to a front surface of the electronic device EA. The image IM may include a static image as well as a dynamic image. FIG. 1 illustrates icon images as examples of the image IM.

In the present disclosure, “on a plane (e.g., in plan view)” may be defined by a state of being seen in the third direction DR3. In the present disclosure, “on a cross-section” may be defined by a state of being seen in the first direction DR1 or the second direction DR2. In one or more embodiments, the directions indicated by the first to third directions DR1, DR2, and DR3 are relative concepts and may be changed to other directions.

FIG. 1 illustrates the electronic device EA having a planar display surface IS. However, a form of the electronic device EA is not limited thereto, and the electronic device EA may have a curved form or a three-dimensional form.

The electronic device EA may be flexible. The term “flexible” refers to bendable properties and may include all of a completely foldable structure to a few nanometer bendable structure. For example, the flexible electronic device EA may include a curved electronic device or a foldable electronic device.

The display surface IS of the electronic device EA may include an active region ED-AA and a peripheral region ED-NAA. A user may see the image IM through the active region ED-AA. According to one or more embodiments as illustrated in FIG. 1 and/or the like, it is illustrated that the active region ED-AA has a rectangular shape (e.g., a substantially rectangular shape), but this is an example, and the active region ED-AA may have one or more suitable shapes.

The peripheral region ED-NAA may be a non-display part that does not display the image IM. The peripheral region ED-NAA may be a part having a set or predetermined color and blocking light. The peripheral region ED-NAA may be adjacent to the active region ED-AA. For example, the peripheral region ED-NAA may be arranged outside at least one side of the active region ED-AA and may be around (e.g., surround) the active region ED-AA. However, this is an example, and the peripheral region ED-NAA may be adjacent to only one side of the active region ED-AA or may be arranged on not a front surface, but a side surface of the electronic device EA, and embodiments of the present disclosure are not limited thereto, and the peripheral region ED-NAA may not be provided.

In one or more embodiments, the peripheral region ED-NAA according to one or more embodiments may be to sense an external input applied from an outside thereof. The external input may have one or more suitable forms, such as pressure, temperature, and/or light, provided from the outside thereof. The external input may include not only a contact with the electronic device EA (for example, a contact by a user's hand or a pen), but also an input (for example, hovering) applied proximate or adjacent to the display device (EA).

Referring to FIG. 2, the electronic device EA may include a display device DD and a housing HAU. The display device DD may include a display module DM, a window WM on the display module DM, and a light-shielding layer SL below the display module DM. The display device DD and the housing HAU may be combined with each other to define an exterior of the electronic device EA. The housing HAU may be to provide an inner surface capable of accommodating members, such as the display module DM and/or the like.

The window WM may be arranged on the display module DM. The window WM may be to protect the display module DM from an external shock. A front surface of the window WM may correspond to the display surface IS of the electronic device EA as described in one or more embodiments. The front surface of the window WM may include a transmission region TA and a bezel region BA.

The transmission region TA of the window WM may be an optically transparent (e.g., substantially transparent) region. The window WM may be to transmit an image provided by the display module DM through the transmission region TA, and a user may see the image. The transmission region TA may correspond to the active region ED-AA of the electronic device EA.

The window WM may include an optically transparent (e.g., substantially transparent) insulating (e.g., electrically insulating) material. For example, the window WM may include glass, sapphire, and/or plastic. The window WM may have a single-layered structure or a multi-layered structure. The window WM may further include functional layers, such as an anti-fingerprint layer, a phase control layer, and a hard coating layer arranged on an optically transparent (e.g., substantially transparent) substrate.

The bezel region BA of the window WM may be provided as a region on which a material including a set or predetermined color is deposited, applied, or printed. The bezel region BA of the window WM may be to prevent one configuration or arrangement of the display module DM overlapping the bezel region BA from being seen to the outside (or to reduce a degree to or occurrence of which one configuration or arrangement of the display module DM overlapping the bezel region BA is seen to the outside). The bezel region BA may correspond to the peripheral region ED-NAA of the electronic device EA.

The display module DM may be to display an image in response to an electrical signal. The display module DM may include a display region DA and a non-display region NDA adjacent to the display region DA.

The display region DA may be a part corresponding to the active region ED-AA of the electronic device EA. The display region DA may be a region activated in response to an electrical signal. The display region DA may be a region from which the image provided by the display module DM comes. The display region DA of the display module DM may correspond to the transmission region TA as described in one or more embodiments. In the present disclosure, “one region/part corresponds to another region/part” refers to “overlap each other” and is not limited to substantially the same area and/or substantially the same shape. The image displayed on the display region DA may be seen from the outside through the transmission region TA.

The non-display region NDA may be adjacent to the display region DA. For example, the non-display region NDA may be around (e.g., surround) the display region DA. However, embodiments of the present disclosure are not limited thereto, and the non-display region NDA may be defined in one or more suitable shapes. The non-display region NDA may be a part corresponding to the peripheral region ED-NAA of the electronic device EA. The non-display region NDA may be a part on which a driving circuit to drive the display region DA, one or more suitable signal lines providing electronic signals, and pads are arranged. The non-display region NDA of the display module DM may correspond to the bezel region BA as described in one or more embodiments. Configurations or arrangements on the non-display region NDA may be prevented from being seen to the outside by the bezel region BA (or a degree or occurrence of which configurations or arrangements on the non-display region NDA are seen to the outside by the bezel region BA may be reduced).

The light-shielding layer SL may be arranged on the display module DM. The light-shielding layer SL may be directly arranged below the display module DM. The light-shielding layer SL may be to at least partially absorb light incident from the outside of the electronic device EA to the display module DM. Because the light provided from the outside of the electronic device EA is at least partially absorbed in the light-shielding layer SL, light reflected on the electronic device EA and emitted to the outside thereof may be minimized or reduced.

The housing HAU may be arranged below the display module DM to accommodate the display module DM and the light-shielding layer SL. The housing HAU may be to protect the display module DM by absorbing a shock added from the outside and preventing or reducing a foreign matter/moisture and/or the like infiltrating the display module DM. The housing HAU according to one or more embodiments may be provided in a form in which a plurality of accommodation members are combined therewith.

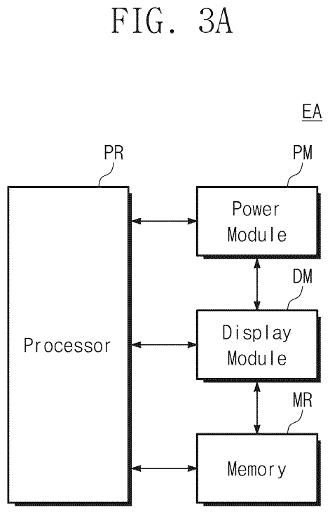

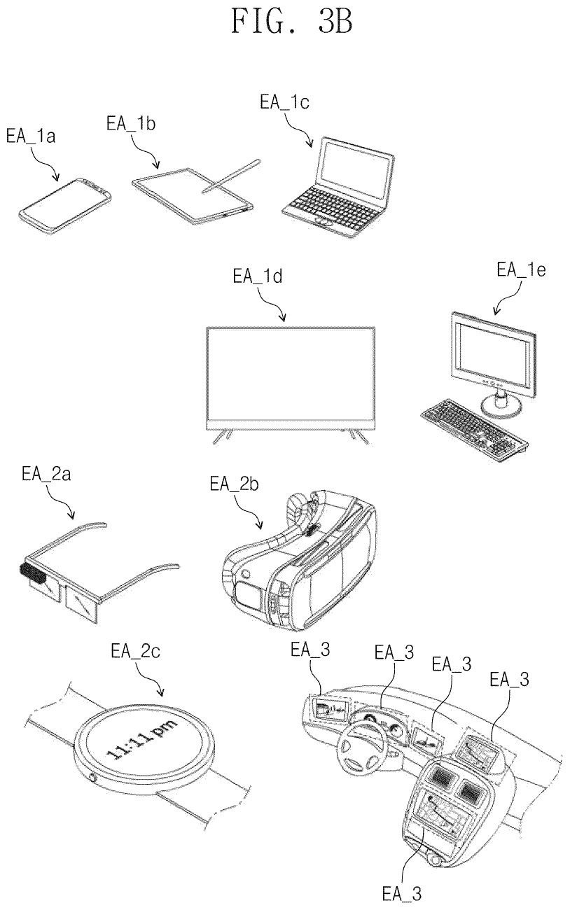

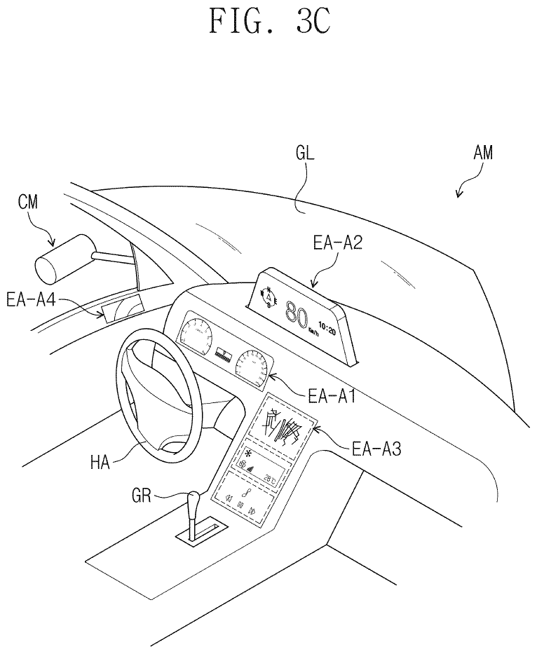

Referring to FIG. 3A, the electronic device EA according to one or more embodiments may include the display module DM, a processor PR, a memory MR, and a power module PM.

The processor PR may include at least one of a central processing unit (CPU), an application processor (AP), a graphic processing unit (GPU), a communication processor (CP), an image signal processor (ISP), or a controller.

Data information necessary or desired for an operation of the processor PR or the display module DM may be stored in the memory MR. If (e.g., when) the processor PR performs an application stored in the memory MR, an image data signal and/or an input control signal may be transferred to the display module DM, and the display module DM may process the provided signal to output image information through the display screen. The display module DM may include a display panel that displays the image.

The power module PM may include a power supply module, such as a power adapter or a battery device, and a power transformation module that transforms power supplied by the power supply module and that generates power necessary or desired for an operation of the electronic device EA.

At least one selected from among the configurations or arrangements of the electronic device EA as described in one or more embodiments may be included in the display module according to one or more embodiments to be described herein and in the display device according to one or more embodiments including the display module. In one or more embodiments, one or more of separate modules functionally included in one module may be included in the display device, and others may be provided separated from the display device. For example, the display device may include the display module DM, and the processor PR, the memory MR, and the power module PM may be provided in forms of other devices in the electronic device EA, not the display device.

FIG. 3B are schematic diagrams of one or more suitable electronic devices according to one or more embodiments.

Referring to FIG. 3B, one or more suitable electronic devices including the display module according to one or more embodiments may include not only an electronic device to display an image, such as a smart phone EA_1a, a tablet computer EA_1b, a laptop computer EA_1c, a TV EA_1d, and a monitor for a desk EA_1e, but also a wearable electronic device, such as a smart glasses EA_2a, a head mount display EA_2b, and a smart watch EA_2c, and an electronic device for a vehicle EA_3, such as a center information display and a room mirror display arranged on an instrument cluster, a center fascia, and a dashboard of a car.

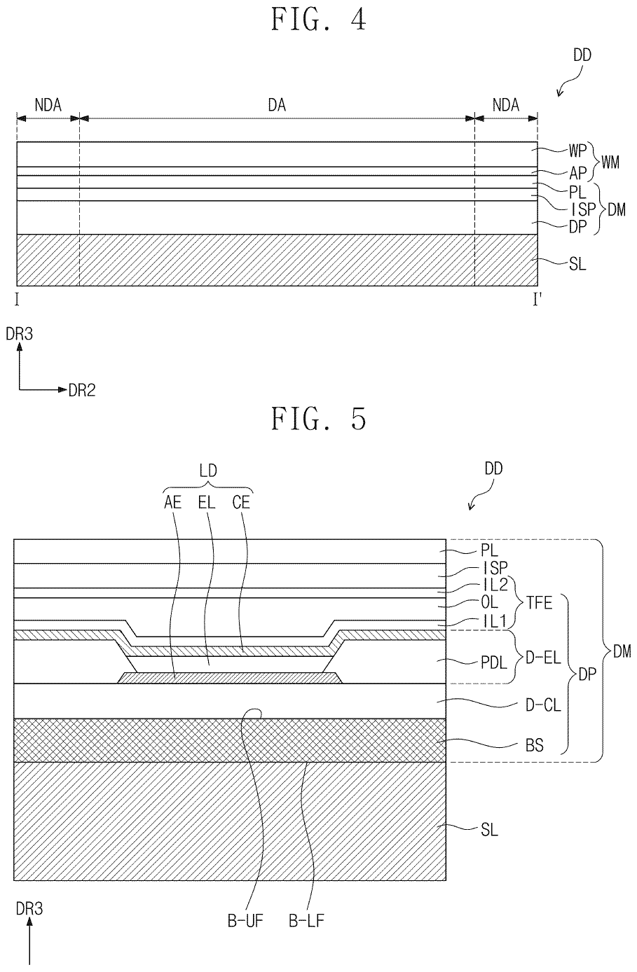

FIG. 3C is a diagram illustrating a vehicle AM in which first to fourth electronic devices EA-1, EA-2, EA-3, and EA-4 are arranged. At least one selected from among the first to fourth electronic devices EA-1, EA-2, EA-3, and EA-4 may include a display module according to one or more embodiments to be described herein with reference to FIGS. 4 and 5.

FIG. 3C illustrates that the vehicle AM is a car, but this is an example, and the first to fourth electronic devices EA-1, EA-2, EA-3, and EA-4 may be arranged in other transportation means, such as a bicycle, a motorcycle, a train, a boat, and an airplane.

At least one selected from among the first to fourth electronic devices EA-1, EA-2, EA-3, and EA-4 may include a light-emitting element LD according to one or more embodiments to be described herein with reference to FIGS. 4 and 5. At least one selected from among the first to fourth electronic devices EA-1, EA-2, EA-3, and EA-4 may include an amine compound according to one or more embodiments. Accordingly, the first to fourth electronic devices EA-1, EA-2, EA-3, and EA-4 including the amine compound according to one or more embodiments may improve or enhance display lifespan. In one or more embodiments, the first to fourth electronic devices EA-1, EA-2, EA-3, and EA-4 including the amine compound according to one or more embodiments may exhibit excellent or suitable display quality and improved or enhanced reliability properties.

Referring to FIG. 3C, the vehicle AM may include a handle HA and a gear GR to control operation thereof, and a front window GL arranged on a front surface of a driver.

The first electronic device EA-1 may be a digital cluster that displays first information of the vehicle AM. The first information may include a first scale indicating a driving speed, a second scale indicating revolutions per minute (RPM) of an engine, an image indicating a fuel state, and/or the like. The first scale and the second scale may be indicated as digital images. In one or more embodiments as illustrated in FIG. 3C, the first electronic device EA-1 may be arranged in a first region overlapping the handle HA. However, embodiments of the present disclosure are not limited thereto, and the first electronic device EA-1 may be arranged on the dashboard of a front surface or may be arranged separated on each of a part opposite to (e.g., facing) a driver's seat and a part opposite to (e.g., facing) a passenger's seat.

The second electronic device EA-2 may be arranged in a second region between the driver's seat and the front window GL. For example, the second electronic device EA-2 may be a head up display (HUD) that displays second information of the vehicle AM. The second electronic device EA-2 may be optically transparent (e.g., substantially transparent). The second information may include a digital number indicating the driving speed and may further include information, such as current time. Unlike what is illustrated, the second information of the second electronic device EA-2 may be projected onto the front window GL and may be indicated. A display surface of the second electronic device EA-2 may be opposite to (e.g., face) the driver's seat. In one or more embodiments, the second electronic device EA-2 may be to provide an image in a front window GL direction.

The third electronic device EA-3 may be arranged in a third region adjacent to the gear GR. For example, the third electronic device EA-3 may be a center information display (CID) that is arranged between the driver's seat and the passenger's sea, and that displays third information. The passenger's seat may be a seat spaced and/or apart (e.g., spaced apart or separated) from the driver's seat with the gear GR therebetween. The third information may include information about a road status (for example, navigation information), playing music or a radio, playing a dynamic image, temperature inside the vehicle AM, and/or the like.

The fourth electronic device EA-4 may be arranged in a fourth region spaced and/or apart (e.g., spaced apart or separated) from the handle HA and the gear GR, and adjacent to a side portion of the vehicle AM. For example, the fourth electronic device EA-4 may be a digital side mirror that displays fourth information. The fourth electronic device EA-4 may be to display an external image of the vehicle AM captured by a camera module CM arranged outside the vehicle AM. The fourth information may include the external image of the vehicle AM.

The first to fourth information as described in one or more embodiments are examples, and the first to fourth electronic devices EA-1, EA-2, EA-3, and EA-4 may further display information about the inside and the outside of the vehicle. The first to fourth information may include information different from each other. However, embodiments of the present disclosure are not limited thereto, and one or more of the first to fourth information may include substantially the same information.

FIG. 3C illustrates an example of an electronic device or an example including the electronic device, and one or more embodiments of the electronic device are not limited thereto.

FIG. 4 is a cross-sectional view of a display panel DD according to one or more embodiments of the present disclosure. FIG. 5 is a partially enlarged cross-sectional view of the display device DD according to one or more embodiments of the present disclosure. In FIG. 5, one or more of configurations or arrangements of the display device DD may not be provided, and configurations or arrangements of the display module DM and the light-shielding layer SL are illustrated in more detail. FIG. 5 illustrates only one light-emitting element and surroundings thereof in the display region DA (see FIG. 2), and description made with reference to FIG. 5 may be substantially identically applied to other light-emitting elements and surroundings thereof in the display region DA (see FIG. 2).

Referring to FIGS. 4 and 5, the display device DD according to one or more embodiments may include the display module DM, the window WM on the display module DM, and the light-shielding layer SL below the display module DM. The display module DM according to one or more embodiments may include a display panel DP and an input sensor ISP on the display panel DP. In one or more embodiments, the display module DM according to one or more embodiments may further include an optical layer PL on the input sensor ISP.

In the display device DD according to one or more embodiments, the display panel DP may be a configuration or arrangement that substantially generates an image. The display panel DP may be a light-emitting display panel, and, for example, may be an organic light-emitting display panel, an inorganic light-emitting display panel, a quantum dot display panel, a micro-LED display panel, or a nano-LED display panel. The display panel DP may be referred to as a display layer.

Referring to FIGS. 4 and 5, the display module DM may further include the optical layer PL arranged on the display panel DP. The optical layer PL may be arranged on the input sensor ISP. The optical layer PL may be a reflection reduction layer that reduces reflectance of external light incident from the outside of the display module DM. The optical layer PL may be formed on the input sensor ISP through a substantially continuous process. According to one or more embodiments, the optical layer PL may include a polarization layer.

For example, the optical layer PL may include the polarization layer including a retarder and/or a polarizer, multi-layered reflective layers destructively interfering reflective light, or color filters arranged corresponding to pixel array and light-emitting colors of the display panel DP. For example, if (e.g., when) the optical layer PL includes the color filters, the color filters may be arranged in consideration of the light-emitting colors of pixels included in the display panel DP. In one or more embodiments, the optical layer PL may not be provided.

The display device DD according to one or more embodiments may include the light-shielding layer SL arranged on a lower side of the display module DM. The light-shielding layer SL may be directly arranged below the display module DM. The light-shielding layer SL may be to at least partially absorb light incident from the outside of the display device DD to the display module DM. Because the light provided from the outside of the display device DD is at least partially absorbed in the light-shielding layer SL, light reflected on the display device DD and emitted to the outside thereof may be minimized or reduced.

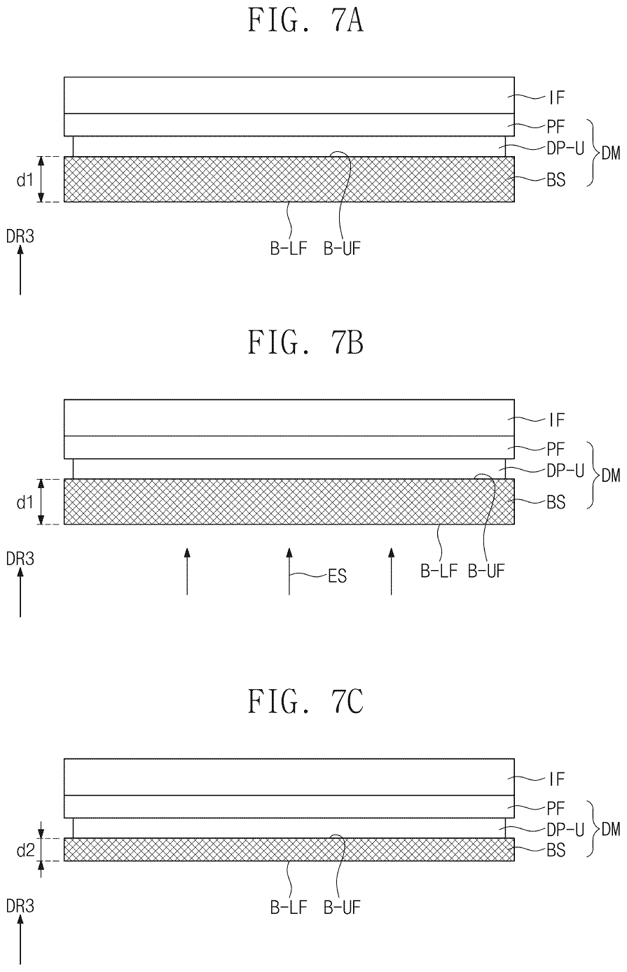

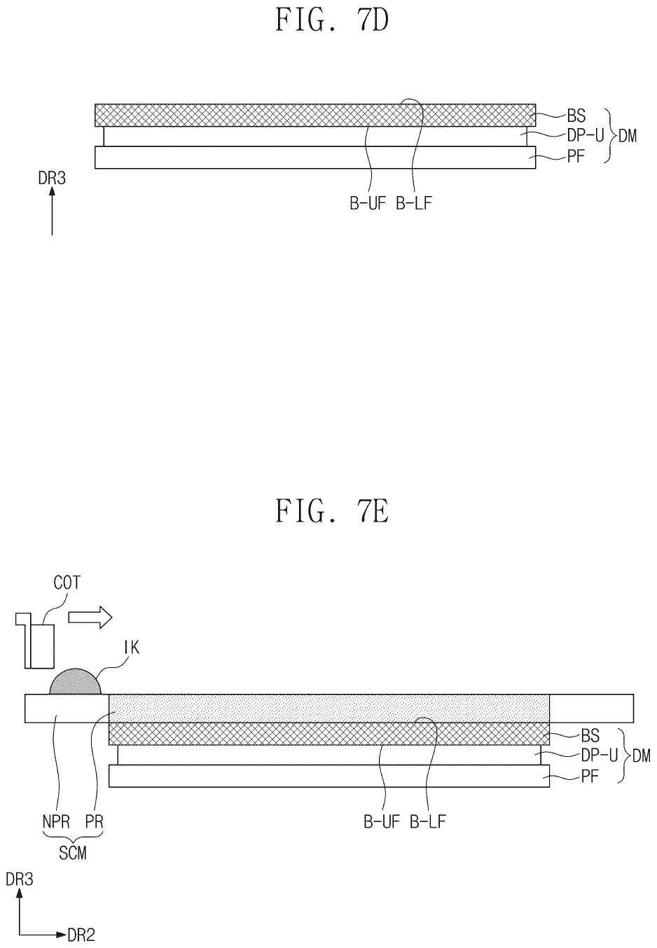

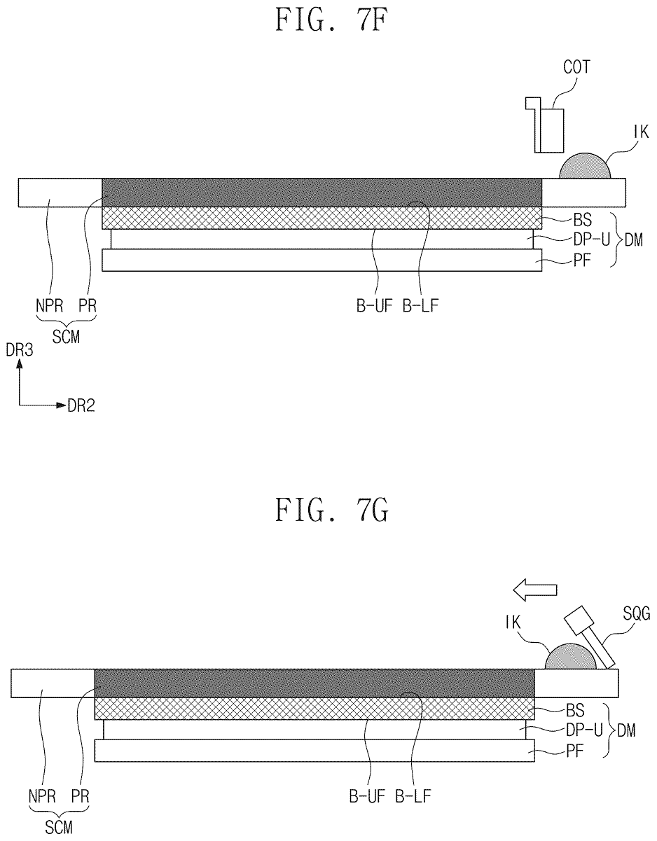

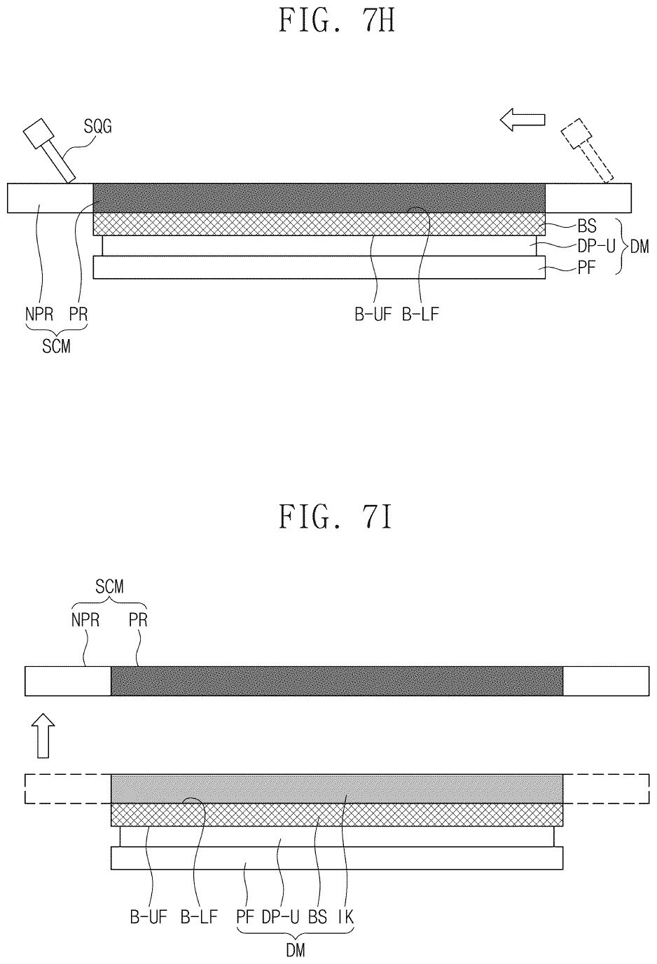

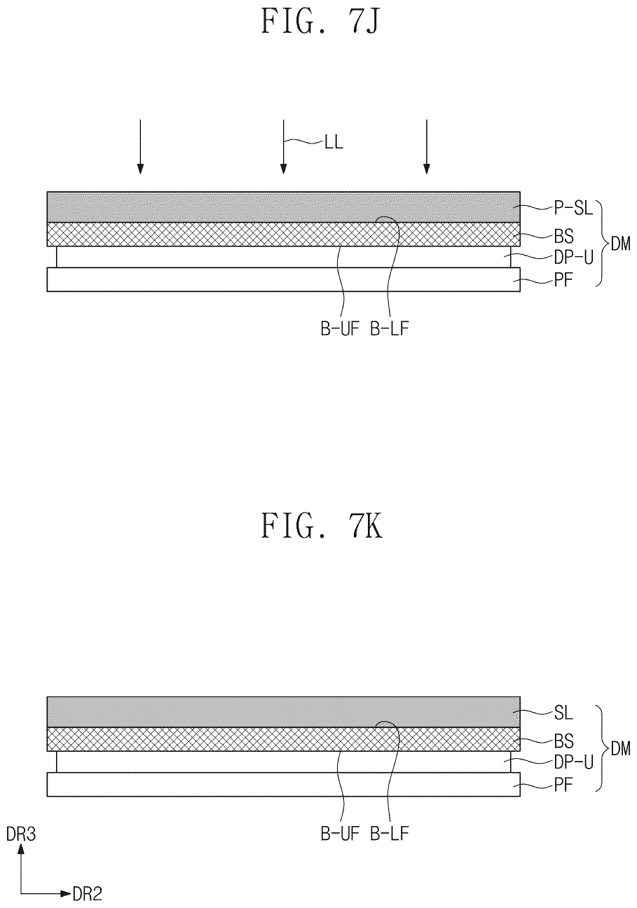

In one or more embodiments, the display device DD according to one or more embodiments may further include a panel protection film PF (see FIG. 7K) arranged on an upper side of the display module DM. The panel protection film PF (see FIG. 7K) may be arranged between the display module DM and the window WM. The panel protection film PF (see FIG. 7K) may be a layer arranged on the upper side of the display module DM and protecting an upper surface of the display module DM. The panel protection film PF (see FIG. 7K) may entirely (e.g., substantially entirely) overlap the display module DM. However, embodiments of the present disclosure are not limited thereto, and the panel protection film PF (see FIG. 7K) may not be provided in the display device DD according to one or more embodiments.

Referring to FIG. 5, the display module DM may include the display panel DP, the input sensor ISP, and the optical layer PL. The display panel DP according to one or more embodiments may include a base layer BS, a circuit layer D-CL, a display element layer D-EL, and an encapsulation layer TFE. According to one or more embodiments, the light-shielding layer SL may be arranged below the base layer BS. The light-shielding layer SL may be directly arranged below the base layer BS. The light-shielding layer SL may be in contact with a lower surface of the base layer BS.

The base layer BS may be a member which provides a base surface on which the circuit layer D-CL is arranged. The base layer BS may be a rigid substrate or a flexible substrate which is bendable, foldable, rollable, and/or the like. The base layer BS may be a glass substrate, a metal substrate, a polymer substrate, and/or the like. However, embodiments of the present disclosure are not limited thereto, and the base layer BS may be an inorganic layer, an organic layer, or a composite material layer. According to one or more embodiments, the base layer BS may be a glass substrate.

Referring to FIG. 5, the base layer BS may include an upper surface B-UF and a lower surface B-LF opposite to each other with respect to the third direction DR3, which is a thickness direction. The upper surface B-UF of the base layer BS may be a surface adjacent to the display element layer D-EL, and the lower surface B-LF of the base layer BS may be a surface opposite to the upper surface B-UF and spaced and/or apart (e.g., spaced apart or separated) from the display element layer D-EL. The lower surface B-LF of the base layer BS may be a surface adjacent to the light-shielding layer SL. The lower surface B-LF of the base layer BS may be in contact with the light-shielding layer SL.

The circuit layer D-CL may be arranged on the base layer BS. The circuit layer D-CL may include a plurality of insulating (e.g., electrically insulating) layers, a plurality of transistors, a conductive (e.g., electrically conductive) pattern, a signal line, and/or the like. According to one or more embodiments, a plurality of inorganic films, a plurality of organic films, a semiconductor layer, and a conductive (e.g., electrically conductive) layer may be formed in a process, such as coating and/or deposition. Thereafter, the inorganic films, the organic films, the semiconductor layer, and the conductive layer may be selectively patterned in a photolithography process. The circuit layer D-CL including a plurality of insulating (e.g., electrically insulating) layers respectively formed from the inorganic films and the organic films, transistors including a semiconductor pattern formed from the semiconductor layer, and a conductive (e.g., electrically conductive) pattern and a signal line formed from the conductive layer may be formed in such processes. Configurations or arrangements of the circuit layer D-CL are briefly illustrated in FIG. 5, and the transistor and the signal line of the circuit layer D-CL and the light-emitting element LD and/or the like of the display element layer D-EL may be electrically connected.

Thereafter, the display element layer D-EL may be formed on the circuit layer D-CL, and the encapsulation layer TFE covering the display element layer D-EL may be formed.

The display element layer D-EL may include a pixel-defining film PDL and the light-emitting element LD. The light-emitting element LD may include a first electrode AE, a light-emitting layer EL, and a second electrode CE.

In one or more embodiments, the first electrode AE may be referred to as a pixel electrode. The first electrode AE may be formed or composed of a metal material, a metal alloy, or a conductive (e.g., electrically conductive) compound. The first electrode AE may be an anode or a cathode. The first electrode AE may be a transmissive electrode, a transflective electrode, or a reflective electrode. If (e.g., when) the first electrode AE is a transmissive electrode, the first electrode AE may include a transparent (e.g., substantially transparent) metal oxide, for example, indium tin oxide (ITO), indium zinc oxide (IZO), zinc oxide (e.g., ZnO), and indium tin zinc oxide (ITZO). If (e.g., when) the first electrode AE is a transflective electrode or a reflective electrode, the first electrode AE may include silver (Ag), magnesium (Mg), copper (Cu), aluminum (AI), platinum (Pt), palladium (Pd), gold (Au), nickel (Ni), neodymium (Nd), iridium (Ir), chromium (Cr), lithium (Li), calcium (Ca), LiF/Ca, LiF/Al, molybdenum (Mo), titanium (Ti), tungsten (W), or a compound or a (e.g., any suitable) mixture thereof (for example, a mixture of Ag and Mg). In one or more embodiments, the first electrode AE may have a multi-layered structure including a reflective film or a transflective film formed or composed of a material as described in one or more embodiments, and a transparent (e.g., substantially transparent) conductive (e.g., electrically conductive) film formed or composed of indium tin oxide (ITO), indium zinc oxide (IZO), zinc oxide (e.g., ZnO), indium tin zinc oxide (ITZO), and/or the like. For example, the first electrode AE may have a three-layered structure of ITO/Ag/ITO, but embodiments of the present disclosure are not limited thereto. Also, embodiments of the present disclosure are not limited thereto, and the first electrode AE may include a metal material as described in one or more embodiments, a combination of at least two metal materials selected from among the metal materials as described in one or more embodiments, oxides of the metal materials as described in one or more embodiments, and/or the like.

The pixel-defining film PDL may be arranged on the circuit layer D-CL. According to one or more embodiments, the pixel-defining film PDL may be formed or made of a polymer resin. For example, the pixel-defining film PDL may include a polyacrylate-based resin or a polyimide-based resin. Also, the pixel-defining film PDL may additionally include an inorganic material in addition to the polymer resin. In one or more embodiments, the pixel-defining film PDL may include a light-absorbing material, a black pigment, and/or a black dye. The pixel-defining film PDL including a black pigment or a black dye may be to perform a black pixel-defining film. If (e.g., when) the pixel-defining film PDL is formed, carbon black and/or the like may be used as the black pigment or the black dye, but embodiments of the present disclosure are not limited thereto.

In one or more embodiments, the pixel-defining film PDL may be formed or composed of an inorganic material. For example, the pixel-defining film PDL may include silicon nitride, silicon oxide, silicon oxynitride, and/or the like.

A pixel opening partially exposing the first electrode AE may be defined in the pixel-defining film PDL. Light-emitting regions may be separated in the display module DM according to one or more embodiments by the pixel-defining film PDL. The light-emitting region in the display module DM may be defined a part in which the first electrode AE is exposed without overlapping the pixel-defining film PDL and overlaps the light-emitting layer EL.

The light-emitting layer EL may be arranged on the first electrode AE in the light-emitting element LD. In the present disclosure, the light-emitting layer EL may be to emit light having at least one of blue, red, or green. In one or more embodiments, the light-emitting layer EL in the entire display region DA (see FIG. 2) may be to provide blue light, and in this case, the display module DM may further include a configuration or arrangement of a light control portion changing a wavelength of light emitted by the light-emitting element LD.

The second electrode CE may be arranged on the light-emitting layer EL. The second electrode CE may have an integrated shape and may be commonly arranged in a plurality of light-emitting elements arranged in the display region DA (see FIG. 2). The second electrode CE may be referred to as a common electrode. The second electrode CE may be an anode or a cathode. For example, if (e.g., when) the first electrode AE is an anode, the second electrode CE may be a cathode, and if (e.g., when) the first electrode AE is a cathode, the second electrode CE may be an anode.

The second electrode CE may be a transmissive electrode, a transflective electrode, or a reflective electrode. If (e.g., when) the second electrode CE is a transmissive electrode, the second electrode CE may be composed of a transparent (e.g., substantially transparent) metal oxide, for example, indium tin oxide (ITO), indium zinc oxide (IZO), zinc oxide (e.g., ZnO), indium tin zinc oxide (ITZO), and/or the like. In one or more embodiments, the second electrode CE may include Ag, Mg, Cu, Al, Pt, Pd, Au, Ni, Nd, Ir, Cr, Li, Ca, LiF/Ca, LiF/Al, Mo, Ti, W, or a compound or a (e.g., any suitable) mixture thereof (for example, a mixture of Ag and Mg).

In one or more embodiments, a hole control layer may be arranged between the first electrode AE and the light-emitting layer EL. The hole control layer may include a hole transport layer and may further include a hole injection layer. An electron control layer may be arranged between the light-emitting layer EL and the second electrode CE. The electron control layer may include an electron transport layer and may further include an electron injection layer. The hole control layer and the electron control layer may be commonly formed in the plurality of light-emitting elements in the entire display region DA (see FIG. 2) utilizing an open mask.

The encapsulation layer TFE may be arranged on the display element layer D-EL. The encapsulation layer TFE may include a first inorganic layer IL1, an organic layer OL, and a second inorganic layer IL2 sequentially stacked. However, layers forming the encapsulation layer TFE are not limited thereto.

The inorganic layers IL1 and IL2 may be to protect the display element layer D-EL from moisture and/or oxygen, and the organic layer OL may be to protect the display element layer D-EL from a foreign matter, such as a dust particle. The inorganic layers IL1 and IL2 may include at least one of silicon nitride, silicon oxide, silicon oxynitride, titanium oxide, or aluminum oxide. The organic layer OL may include an acrylate organic material. However, types (kinds) of materials forming the inorganic layers IL1 and IL2 and the organic layer OL are not limited thereto.

The input sensor ISP may be arranged on the encapsulation layer TFE. According to one or more embodiments, the input sensor ISP may include insulating (e.g., electrically insulating) layers and a sensor conductive (e.g., electrically conductive) layer. According to one or more embodiments, the input sensor ISP may be directly arranged on the encapsulation layer TFE.

The display module DM according to one or more embodiments may include the optical layer PL. The optical layer PL according to one or more embodiments may be directly arranged on the input sensor ISP. However, embodiments of the present disclosure are not limited thereto, and an adhesive layer and/or the like may be further included between the optical layer PL and the input sensor ISP. The optical layer PL may be a reflection reduction layer that reduces external light. In one or more embodiments, the optical layer PL may not be provided.

In one or more embodiments, the light-shielding layer SL may be an optical member arranged below the display module DM and absorbing light incident through the display module DM and may be to function as a support member supporting the display module DM.

In one or more embodiments, the light-shielding layer SL may be formed or made from an ink composition according to one or more embodiments to be described herein. The light-shielding layer SL may be directly provided on the lower surface B-LF of the base layer BS and may be in contact with the lower surface B-LF of the base layer BS. The light-shielding layer SL may include a light-shielding material. For example, the light-shielding layer SL may include a pigment, such as carbon black, as the light-shielding material. The light-shielding layer SL may be a layer including a material having a set or predetermined color to have a color.

The light-shielding layer SL may have a thickness in a range of about 9 μm to about 16 μm. For example, the light-shielding layer SL may have a thickness of about 12 μm. The light-shielding layer SL may have excellent or suitable light-shielding properties by satisfying the thickness of the range as described herein and may exhibit excellent or suitable durability and reliability properties by protecting the functional layers arranged on the display module DM due to a sufficient or suitable thickness.

The light-shielding layer SL may be a single layer formed through one process. For example, the light-shielding layer SL may not include (e.g., may exclude) a plurality of layers separated from each other with an interface therebetween and may be formed or composed of one layer having an integrated shape. However, embodiments of the present disclosure are not limited thereto, and the light-shielding layer SL may include a plurality of layers.

According to one or more embodiments, the light-shielding layer SL may be directly arranged below the base layer BS. The light-shielding layer SL may be directly arranged on the base layer BS without a separate adhesive member. The light-shielding layer SL may be formed by providing an ink composition according to one or more embodiments to be described herein, and then photocuring the applied ink composition. In one or more embodiments, the light-shielding layer SL may be formed by providing the ink composition according to one or more embodiments on a lower side of the display module DM in a screen printing process, and photocuring the provided ink composition.

Hereinafter, the ink composition according to one or more embodiments of the present disclosure will be described.

The ink composition according to one or more embodiments of the present disclosure may be utilized so as to form the light-shielding layer SL of the display module DM as described with reference to FIGS. 4 and 5. For example, the ink composition according to one or more embodiments of the present disclosure may be applied and cured on a rear surface of the display module DM to form the light-shielding layer SL on the rear surface of the display module DM.

The ink composition according to one or more embodiments of the present disclosure may suppress or reduce flowability by including a mill base including a carbon nanotube, and as a result, may prevent a defect (or reduce a degree or occurrence of a defect) caused by smearing of the ink composition in forming the light-shielding layer. For example, a smearing defect occurring at an end part of the light-shielding layer may be prevented (or a degree or occurrence of a smearing defect occurring at an end part of the light-shielding layer may be reduced) in forming the light-shielding layer through the screen printing process to be described herein with reference to FIGS. 7E to 7K.

The ink composition according to one or more embodiments of the present disclosure may include a first mill base, a base resin, a pigment, and a photo initiator. The first mill base may include a carbon nanotube, a first dispersant, and at least one first (meth)acrylate monomer, and the mill base may serve as an intermediate dispersion to ensure uniform (e.g., substantially uniform) distribution of the carbon nanotube within the ink composition.

In one or more embodiments, the carbon nanotube may have an average aspect ratio of about 2000 to about 5000. The average aspect ratio of the carbon nanotube may be defined as a ratio of an average length to an average diameter of the carbon nanotube in the ink composition.

The average diameter of the carbon nanotube may be determined as the mean of measured diameters of 50 randomly selected carbon nanotubes in the ink composition. Similarly, the average length of the carbon nanotube may be determined as the mean of measured lengths of 50 randomly selected carbon nanotubes in the ink composition. For example, the average diameter and average length may be calculated based on measurements obtained from scanning electron microscopy (SEM) or transmission electron microscopy (TEM) images. The average aspect ratio may then be calculated as the ratio of the average length to the average diameter determined by the above method. For example, the average diameter of the carbon nanotube may be an average of measured diameters of 50 arbitrary carbon nanotubes selected in the ink composition. The average length of the carbon nanotube may be an average of measured lengths of 50 arbitrary carbon nanotubes selected in the ink composition. For example, the average diameter and the average grain size of the carbon nanotubes may be an average value obtained by measuring and calculating the diameter and the grain size of 50 arbitrary carbon nanotubes selected in a SEM image or a TEM image. The average aspect ratio may be a ratio of the average diameter to the average grain size calculated in the method as described herein. As used herein, the term “diameter” refers to the cross-sectional diameter of the carbon nanotube if (e.g., when) the cross-section is substantially circular, and refers to the length of the major axis of the cross-section when the cross-section is non-circular.

The carbon nanotube may have the average aspect ratio of the range as described herein to be uniformly (e.g., substantially uniformly) dispersed in the first mill base, and then a thixotropic index (hereinafter T.1) of the ink composition including the first mill base may be increased. Through this, smearing in the screen printing process may be prevented (or a degree or occurrence of smearing in the screen printing process may be reduced) by suppressing or reducing excessive or substantial flowability of the ink composition. In one or more embodiments, the thixotropic index (T.1) of the ink composition may be in a range of about 1.8 to about 2.5 and may be, for example, about 1.9 to about 2.2.

If (e.g., when) the average aspect ratio of the carbon nanotube is smaller than the range as described herein, the thixotropic index (T.1) of the ink composition may not be increased, and as a result, it may be difficult to prevent smearing of the ink composition (or reduce a degree or occurrence of smearing of the ink composition). If (e.g., when) the average aspect ratio of the carbon nanotube is greater than the range as described herein, dispersion may be deteriorated, and the thixotropic index (T.1) of the ink composition may be excessively or substantially increased. Accordingly, the ink composition may not smoothly pass through a screen mask during the screen printing process, and as a result, the ink composition may not be uniformly (e.g., substantially uniformly) applied on a substrate so that (e.g., such that) a defect occurs.

In one or more embodiments, the carbon nanotube may have an average diameter of about 2 nm or less. For example, the carbon nanotube may have an average diameter in a range of about 1 nm to about 2 nm.

In one or more embodiments, the carbon nanotube may have an average length in a range of about 5 nm to about 10 nm.

The carbon nanotube may have the average diameter and the average length to have excellent or suitable conductivity (e.g., electrical conductivity) and dispersion in the ink composition.

In one or more embodiments, the carbon nanotube may include at least one of a single-walled carbon nanotube or a multi-walled carbon nanotube.

The first dispersant may be to uniformly (e.g., substantially uniformly) disperse the carbon nanotube in the first mill base. In one or more embodiments, thereafter, the first dispersant may be to uniformly (e.g., substantially uniformly) disperse carbon black and/or the like in the ink composition.

In one or more embodiments, the ink composition may have a viscosity of about 1000 cP to about 5000 cP at about 25° C. The thixotropic index (T.1) may be increased in the composition having a viscosity of about 1000 cP or less by using an organic thickener, but it may be difficult to increase the thixotropic index (T.1) in a high viscosity composition, such as the ink composition according to the present disclosure having a viscosity of about 1000 cP or more by using the organic thickener.

In one or more embodiments, the first dispersant may have at least one of aminga or sanga. For example, the dispersant may have any one selected from among aminga and sanga or may concurrently (e.g., simultaneously) have aminga and sanga. If (e.g., when) the dispersant has the aminga, the aminga may be in a range of about 1 mg KOH/g to about 120 mg KOH/g. In one or more embodiments, if (e.g., when) the dispersant has the sanga, the sanga may be in a range of about 1 mg KOH/g to about 120 mg KOH/g. For example, “aminga” and “sanga” respectively refer to functional groups that may be characterized by an amine value or an acid value. If (e.g., when) the dispersant includes aminga, the amine value may be in a range of about 1 mg KOH/g to about 120 mg KOH/g. Similarly, if (e.g., when) the dispersant includes sanga, the acid value may be in a range of about 1 mg KOH/g to about 120 mg KOH/g. However, embodiments of the present disclosure are not limited thereto.

A non-ionic dispersant, an anionic dispersant, a cationic dispersant, and/or the like may be used as the first dispersant, but embodiments of the present disclosure are not limited thereto. Example of the first dispersant may include polyalkylene glycol and ester thereof, polyoxyalkylenes, a polyhydric alcohol ester alkylene oxide adduct, an alcohol alkylene oxide adduct, sulfonic acid ester, sulfonic acid salt, carboxylic acid ester, carboxylic acid salt, an alkylamide alkylene oxide adduct, alkyl amine, and/or the like, and these may be used alone or at least two thereof may be mixed and used.

The first (meth)acrylate monomer may include at least one (meth)acrylate monomer containing at least one (meth)acrylate monomer in a molecule, that is generally available or generally used.

In general, the (meth)acrylate monomer may be classified as a monofunctional (meth)acrylate monomer (one), a bifunctional (meth)acrylate monomer (two), and a multi-functional (meth)acrylate monomer (three or more) according to the number of the (meth)acrylate group included in one molecule.

In one or more embodiments, examples of the mono-functional (meth)acrylate monomer may include methyl (meth)acrylate, ethyl(meth)acrylate, propyl(meth)acrylate, n-butyl(meth)acrylate, isobutyl(meth)acrylate, tert-butyl(meth)acrylate, 2-ethylhexyl(meth)acrylate, isodecyl(meth)acrylate, isoamyl(meth)acrylate, isomyristyl(meth)acrylate, n-lauryl(meth)acrylate, n-stearyl(meth)acrylate, isostearyl(meth)acrylate, long-chain alkyl(meth)acrylate, n-butoxyethyl(meth)acrylate, butoxydiethyleneglycol(meth)acrylate, cyclohexyl(meth)acrylate, tetrahydrofurfuryl(meth)acrylate, butoxyethyl(meth)acrylate, 2-ethylhexyl-diglycol(meth)acrylate, dicyclopentenyl(meth)acrylate, dicyclopentenyloxyethyl(metha)acrylate, dicyclopentanil(metha)acrylate, benzyl(metha)acrylate, 2-hydroxyethyl(metha)acrylate, 2-hydroxypropyl(metha)acrylate, 2-hydroxybutyl(metha)acrylate, 2-(2-vinyloxyethoxy)ethyl(metha)acrylate, glycidyl(metha)acrylate, methoxyethyleneglycol modified (metha)acrylate, ethoxyethyleneglycol modified (meth)acrylate, propoxyethyleneglycol modified (meth)acrylate, methoxypropyleneglycol modified (meth)acrylate, ethoxypropyleneglycol modified (meth)acrylate, propoxypropyleneglycol modified (meth)acrylate, tetrahydrofuryl(meth)acrylate, acryloyl morpholine, and/or the like.

In one or more embodiments, examples of the monofunctional (meth)acrylate having an aromatic ring may include phenoxymethyl(meth)acrylate, phenoxyethyl(meth)acrylate, phenoxyethyleneglycol modified (meth)acrylate, phenoxypropyleneglycol modified (meth)acrylate, hydroxyphenoxyethyl(meth)acrylate, 2-hydroxy-3-phenoxypropyl(meth)acrylate, hydroxyphenoxyethyleneglycol modified (meth)acrylate, hydroxyphenoxypropyleneglycol modified (meth)acrylate, alkylphenolethyleneglycol modified (meth)acrylate, alkylphenolpropyleneglycol modified (meth)acrylate, ethoxylated o-phenylphenol(meth)acrylate, isobornyl (meth)acrylate and/or the like.

In one or more embodiments, examples of the bifunctional (meth)acrylate monomer may include ethylene glycol di-(meth)acrylate, propylene glycol di-(meth)acrylate, tripropylene glycol di-(meth)acrylate, polyolefin glycol di-(meth)acrylate, polyethylene glycol di-(meth)acrylate, ethoxylated polypropylene glycol di-(meth)acrylate, 2-hydroxy-1,3-dimethacryloxypropane, dioxane glycol di-(meth)acrylate, tricyclodecanedimethanol di-(meth)acrylate, 1,4-butanediol di(meth)acrylate, glycerin di(meth)acrylate, 1,6-hexanediol di(meth)acrylate, 1,9-nonanediol di(meth)acrylate, 1,10-decanediol di(meth)acrylate, neopentyl glycol di(meth)acrylate, 2-methyl-1,8-octanediol di(meth)acrylate, 1,9-nonanediol di(meth)acrylate, butyl ethylpropanediol di(meth)acrylate, 3-methyl-1,5-pentanediol di(meth)acrylate, and/or the like.

In one or more embodiments, examples of the bifunctional (meth)acrylate monomer having an aromatic ring may include ethoxylated bisphenol A di(meth)acrylate, propoxylated and ethoxylated bisphenol A di(meth)acrylate, ethoxylated bisphenol F di(meth)acrylate, and/or the like.

In one or more embodiments, examples of the multi-functional (meth)acrylate monomer may include ethoxylated glycerin tri(meth)acrylate, trimethylolpropane tri(meth)acrylate, ethoxylated trimethylolpropane tri(meth)acrylate, propoxylated trimethylolpropane tri(meth)acrylate, pentaerythritol tri(meth)acrylate, and/or the like (a 3 functional monomer); pentaerythritol tetra(meth)acrylate, ditrimethylolpropane tetra(meth)acrylate, ethoxylated pentaerythritol tetra(meth)acrylate, and/or the like (a 4 functional monomer); dipentaerythritol hexa(meth)acrylate and/or the like (a 5 functional monomer); dipentaerythritol polyacrylate; and/or the like.

In one or more embodiments, the first (meth)acrylate monomer may include at least two monomers having different viscosities. In one or more embodiments, the second (meth)acrylate may include a first monomer having a first viscosity and a second monomer having a second viscosity greater than the first viscosity. The first monomer may be a (meth)acrylate monomer having a relatively low viscosity, and the second monomer may be a (meth)acrylate monomer having a relatively high viscosity.

The first monomer may have a first viscosity in a range of about 1 cP to about 50 cP at about 25° C. For example, the first viscosity may be in a range of about 2 cP to about 20 cP. The first monomer may be added so as to improve or enhance dispersion and storage stability with surface modification of the pigment. Excellent or suitable surface modification properties, dispersion, and storage stability may be secured without using a separate solvent by mixing and milling the first monomer having relatively low viscosity properties with the pigment and the dispersant.

The second monomer may have a second viscosity in a range of about 100 cP to about 10000 cP at about 25° C. For example, the second viscosity may be in a range of about 100 cP to about 5000 cP. The second monomer may be included in the mill base to increase compatibility with one or more suitable base resins. The second monomer may have a relatively higher viscosity than the first monomer to increase the total viscosity of the mill base. The second monomer may be added after a milling process to be described herein. The second monomer may be mixed in the mill base to increase compatibility with the base resin in the ink composition, and thus to further improve or enhance material stability and processability of the ink composition.

In one or more embodiments, a difference between the first viscosity of the first monomer and the second viscosity of the second monomer may be in a range of about 100 cP to about 5000 cP. For example, the difference between the first viscosity and the second viscosity may be in a range of about 1000 cP to about 5000 cP.

The first monomer may have a first viscosity in a range of about 1 cP to about 50 cP at about 25° C. For example, the first viscosity may be in a range of about 2 cP to about 20 cP. The first monomer may be added so as to improve or enhance dispersion and storage stability with surface modification of the pigment. Excellent or suitable surface modification properties, dispersion, and storage stability may be secured without using a separate solvent by mixing and milling the first monomer having relatively low viscosity properties with the pigment and the dispersant.

The second monomer may have a second viscosity in a range of about 100 cP to about 10000 cP at about 25° C. For example, the second viscosity may be in a range of about 100 cP to about 5000 cP. The second monomer may be included in the mill base to increase compatibility with one or more suitable base resins. The second monomer may have a relatively higher viscosity than the first monomer to increase the total viscosity of the mill base. The second monomer may be added after a milling process to be described herein. The second monomer may be mixed in the mill base to increase compatibility with the base resin in the ink composition, and thus to further improve or enhance material stability and processability of the ink composition.

In one or more embodiments, a difference between the first viscosity of the first monomer and the second viscosity of the second monomer may be in a range of about 100 cP to about 5000 cP. For example, the difference between the first viscosity and the second viscosity may be in a range of about 1000 cP to about 5000 cP.

The (meth)acrylate monomer containing at least one (meth)acrylate group in a molecule, that is generally available or generally used, may be used without limitation as the first monomer and the second monomer.

In one or more embodiments, the first monomer may include at least one of 1,6-hexanediol diacrylate (HDDA), tetrahydrofurfuryl acrylate (THFA), isobornyl acrylate (IBOA), 2-hydroxyethyl methacrylate (2-HEMA), tripropylene glycol diacrylate (TPGDA), or trimethylolpropane triacrylate (TMPTA); and the second monomer may include at least one of pentaerythritol tetraacrylate (PETTA), dipentaerythritol pentaacrylate (DPPA), or dipenta erythriol hexaacrylate (DPHA).

In one or more embodiments, 1,6-hexanediol diacrylate may be included as the first monomer, and pentaerythritol tetraacrylate may be included as the second monomer.

In one or more embodiments, with respect to the total content (e.g., amount) of 100% (e.g., based on a total of 100 wt %) of the first mill base, the carbon nanotube of about 5 wt % to about 20 wt % may be included, the first dispersant of about 1 wt % to about 10 wt % may be included, and the first (meth)acrylate monomer of about 70 wt % to about 85 wt % may be included.

In one or more embodiments, the first mill base may not include (e.g., may exclude) a solvent. For example, the first mill base is substantially free of added solvent, except for residual amounts present as impurities or by-products.

The first mill base of about 1 wt % to about 15 wt % may be included with respect to the total content (e.g., amount) of 100% (e.g., based on a total of 100 wt %) of the ink composition.

The base resin may be to control a cross-linking density of the entire applied film. Through this, if (e.g., when) the ink composition is cured, a strength, durability, and a surface hardness of the applied film may be controlled or selected, and an adhesion with another material and/or the like may be improved or enhanced.

In the ink composition according to one or more embodiments, an ingredient that is generally available or generally used in the art may be used without limitation as the base resin. For example, the base resin may include at least one of a (meth)acrylate resin, an imide-based resin, an epoxy-based resin, a urethane-based resin, or a siloxane-based resin. The base resin may be a polymer resin having a weight average molecular weight in a range of about 5000 g/mol to about 50000 g/mol.

In one or more embodiments, the base resin may include at least one of a (meth)acrylate resin or an imide-based resin.

The (meth)acrylate resin may refer to a polymer compound derived from a monomer including an acrylate or a methacrylate functional group in a molecular structure. For example, the (meth)acrylate resin may include at least one of urethane (meth)acrylate, alkyl (meth)acrylate, hydroxyalkyl acrylate, polyethylene glycol alkyl ether methacrylate, perfluorinated alkyl (meth)acrylate, or silicone (meth)acrylate. The imide-based resin may refer to a polymer compound including an imide bonding in a molecular structure. For example, the imide-based resin may include at least one of polyimide or polyamideimide. The imide-based resin may contain the imide bonding to be excellent or suitable in heat-resistance, wear-resistance, chemical resistance, and/or the like.

In one or more embodiments, the base resin may include urethane acrylate.

The base resin in a range of about 25 wt % to about 60 wt % may be included with respect to the total content (e.g., amount) of 100% (e.g., based on a total of 100 wt %) of the ink composition. If (e.g., when) the base resin of the range as described herein is included, excellent or suitable application, adhesiveness, and/or the like may be obtained.

The photo initiator may serve to initiate photopolymerization in the ink composition according to one or more embodiments of the present disclosure by being excited by an ultraviolet ray and/or the like. The photo initiator may have a maximum absorbance in a wavelength region of about 305 nm to about 405 nm. An initiator that is generally available or generally used in the art may be used without limitation as the photo initiator. For example, the photo initiator may include at least one of an acetophenone-based compound, a benzophenone-based compound, a thioxantone-based compound, a benzoin-based compound, an oximeester-based (oxime ester-based) compound, or a triazine-based compound.

In one or more embodiments, examples of the acetophenone-based compound may include 2,2′-diethoxyacetophenone, 2,2′-dibutoxyacetophenone, 2-hydroxy-2-methylpropiophenone, p-t-butyltrichloroacetophenone, p-t-butyldichloroacetophenone, 4-chloroacetophenone, 2,2′-dichloro-4-phenoxyacetophenone, 2-methyl-1-(4-(methylthio)phenyl)-2-morpholinopropan-1-one, 2-benzyl-2-dimethylamino-1-(4-morpholinophenyl)butan-1-one, and/or the like.

In one or more embodiments, examples of the benzophenone-based compound may include benzophenone, benzoyl benzoate, benzoyl benzoate methyl, 4-phenylbenzophenone, hydroxybenzophenone, acrylated benzophenone, 4,4′-bis(dimethylamino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and/or the like.

In one or more embodiments, examples of the thioxantone-based compound may include thioctic acid, 2-crothyloctic acid, 2-methylthioctic acid, isopropyl thioctic acid, 2,4-diethyl thioctic acid, 2,4-diisopropyl thioctic acid, 2-chlorothioctic acid, and/or the like.

In one or more embodiments, examples of the benzoin-based compound may include benzoin, benzoin methyl ether, benzoin ethyl ether, benzoin isopropyl ether, benzoin isobutyl ether, benzyl dimethyl ketal, and/or the like.

In one or more embodiments, examples of the oximeester-based (oxime ester-based) compound may include o-ethoxycarbonyl-α-oxyimino-1-phenylpropan-1-one and/or the like and may include a commercially available compound, such as OXE-01 and OXE-02 from BASF.

In one or more embodiments, examples of the triazine-based compound may include 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl 4,6-bis(trichloromethyl)-S-triazine, bis(trichloromethyl)-6-styryl-S-triazine, 2-(naphtho1-yl)-4,6-bis(trichloromethyl)-S-triazine, 2-(4-methoxynaphtho1-yl)-4,6-s(trichloromethyl)-S-triazine, 2-4-trichloromethyl(piperonyl)-6-triazine, 2-4-trichloromethyl(4′-methoxystyryl)-6-triazine, and/or the like.

The photo initiator may include not only the compound as described in one or more embodiments, but also a carbazole-based compound, a diketone-based compound, a sulfonium borate-based compound, a diazo-based compound, an imidazole-based compound, a biimidazole-based compound, and/or the like.

According to one or more embodiments, the photo initiator may include not only the compound(s) as described above, but also a photo sensitizer, such as isopropylthioxanthone (ITX) or diethylthioxanthone (DETX), and an auxiliary initiator, such as diethylhydroxylamine (DEHA) or diethyldithiocarbamate (DEDH).

The photo initiator in a range of about 5 wt % to about 15 wt % may be included with respect to the total content (e.g., amount) of 100% (e.g., based on a total of 100 wt %) of the ink composition. If (e.g., when) the photo initiator of the range as described herein is included in the ink composition according to the present disclosure, curing may sufficiently or suitably occur during exposure to improve or enhance reliability of the applied film. In one or more embodiments, an excellent or suitable effect may be provided in durability and adhesion of the formed applied film, and a defect caused by the unreacted monomer may be prevented (or a degree or occurrence of a defect caused by the unreacted monomer may be reduced).

The ink composition according to one or more embodiments of the present disclosure may include a pigment. The pigment may be an organic pigment and/or an inorganic pigment.

A black pigment and/or the like may be used as the pigment. The black pigment may include an inorganic black pigment, such as carbon black, an organic black pigment, such as lactam black, aniline black, and perylene-based black pigment, and/or the like.

In one or more embodiments, the ink composition may include at least one black pigment of carbon black, lactam black, aniline black, or perylene black.

The ink composition according to one or more embodiments of the present disclosure may include a second mill base including the pigment as described herein. For example, the pigment in the ink composition may be mixed in a mill base form. For example, the pigment in the ink composition may be incorporated in the form of a mill base.

The second mill base may include a pigment, a second dispersant, and at least one second (meth)acrylate monomer.

The descriptions provided herein may be substantially identically applied to the pigment. For example, the descriptions provided herein with respect to the pigment may be substantially applicable to the pigment in the second mill base.

The descriptions provided herein in the first dispersant may be substantially identically applied to the second dispersant. The second dispersant may be substantially the same as or different from the first dispersant.

The second (meth)acrylate monomer may include at least one selected from among the monomers as described herein about the first (meth)acrylate monomer. The second (meth)acrylate monomer may be substantially the same as or different from the first (meth)acrylate monomer.

In one or more embodiments, with respect to the total weight (e.g., based on a total of 100 wt %) of the second mill base, the pigment in a range of about 5 wt % to about 30 wt % may be included, the second dispersant in a range of about 2 wt % to about 10 wt % may be included, and the second (meth)acrylate monomer in a range of about 60 wt % to about 90 wt % may be included.

In one or more embodiments, the second (meth)acrylate monomer may include at least two monomers having different viscosities. In one or more embodiments, the second (meth)acrylate may include a third monomer having a first viscosity, and a fourth monomer having a second viscosity greater than the first viscosity. The third monomer may be a (meth)acrylate monomer having a relatively low viscosity, and the fourth monomer may be a (meth)acrylate monomer having a relatively high viscosity.

For example, the third monomer may correspond to the first monomer, and the fourth monomer may correspond to the second monomer.

In one or more embodiments, example of the third monomer may include at least selected from among 1,6-hexanediol diacrylate, tetrahydrofurfuryl acrylate, isobornyl acrylate, 2-hydroxyethyl methacrylate, tripropylene glycol diacrylate, and trimethylolpropane triacrylate, wherein the fourth monomer is at least one of pentaerythritol tetraacrylate, dipentaerythritol pentaacrylate, or dipentaerythritol hexaacrylate.

In one or more embodiments, with respect to the total weight (e.g., based on a total of 100 wt %) of the second mill base, the pigment in a range of about 5 wt % to about 30 wt % may be included, the second dispersant in a range of about 2 wt % to about 10 wt % may be included, the first monomer in a range of about 30 wt % to about 45 wt % may be included, and the second monomer in a range of about 30 wt % to about 45 wt % may be included.

In one or more embodiments, the second mill base may not include (e.g., may exclude) a solvent. For example, the second mill base is substantially free of added solvent, except for residual amounts present as impurities or by-products.

The second mill base in a range of about 5 wt % to about 20 wt % may be included with respect to the total content (e.g., amount) of 100% (e.g., based on a total of 100 wt %) of the ink composition.

In one or more embodiments, the ink composition according to one or more embodiments may include a photopolymerization monomer, a coupling agent, and an additive including at least one of an antistatic agent, a leveling agent, or a defoaming agent.

In one or more embodiments, the Ink composition according to one or more embodiments may not include (e.g., may exclude) a solvent. For example, the ink composition is substantially free of added solvent, except for residual amounts present as impurities or by-products.

In addition to the base resin, the photo initiator, and the mill base, the ink composition according to one or more embodiments may further include a photopolymerization monomer, a coupling agent, and an additive including at least one of an antistatic agent, a leveling agent, or a defoaming agent.

The photopolymerization monomer may be used as a reactive diluent of a photoreactive polymer to impart or enhance workability through viscosity control of the ink composition and may be to serve as a cross-linker controlling a cross-linking density between polymers. The photopolymerization monomer may be included in order to support curing properties, such as adhesion and a hardness of the applied film in the applied film formed or composed of the ink composition according to one or more embodiments of the present disclosure.

The photopolymerization monomer may be a monomer (e.g., a photo polymerizable monomer) including two or more polymerizable residues (e.g., two or more polymerizable functional groups). The polymerizable residue may be a (meth)acrylate group, a carbon-carbon double bond, such as a vinyl group, an epoxy group, and/or the like. The photopolymerization monomer according to one or more embodiments may include 2 to 16 polymerizable resides (e.g., 2 to 16 polymerizable functional groups).

In one or more embodiments, the photopolymerization monomer may be a (meth)acrylate monomer. A (meth)acrylate monomer containing two (meth)acrylate groups in a molecule, that is generally available or generally used, may be used without limitation as the (meth)acrylate monomer.

In one or more embodiments, the photopolymerization monomer may have at least two polymerizable functional groups, such as at least two (meth)acrylate groups, in a molecule, and may include a difunctional acryl monomer (two) or a multi-functional acryl monomer (at least three).

The difunctional (meth)acrylate monomer and the multi-functional (meth)acrylate monomer may be separately used as or may be combined and used as the polymerization monomer in the ink composition according to the present disclosure.

The photopolymerization monomer in the ink composition according to one or more embodiments may be substantially the same as the second monomer included in the mill base. Because the photopolymerization monomer is substantially the same as the second monomer, compatibility of the mill base in the ink composition may increase. However, embodiments of the present disclosure are not limited thereto, and the photopolymerization monomer may be different from the second monomer.

In one or more embodiments, the photopolymerization monomer in a range of about 25 wt % to about 60 wt % may be included with respect to the total content (e.g., amount) of 100% (e.g., based on a total of 100 wt %) of the ink composition. Because the content (e.g., amount) of the photopolymerization monomer satisfies the range as described herein, the viscosity and the cross-linking density of the ink composition may be appropriately or suitably controlled or selected to improve or enhance adhesiveness of the cured applied film and workability.

The coupling agent may include at least one of a silane-based compound or a siloxane-based compound. The silane-based compound may serve to impart or enhance adhesion to the applied film formed of a photocurable resin composition, and the siloxane-based compound may serve as a wetting agent imparting or enhancing wettability to the applied film formed of the photocurable resin composition. The coupling agent in a range of about 0.5 wt % to about 3 wt % may be included with respect to the total content (e.g., amount) of 100% (e.g., based on a total of 100 wt %) of the ink composition.

The antistatic agent may serve to prevent electrostatic charging (or reduce a degree or occurrence of electrostatic charging) by lowering surface electrical resistance of the applied film formed of the ink composition. A material that is generally available or generally used in the art may be used without limitation as the antistatic agent. In one or more embodiments, the applied film formed or made from the ink composition including the antistatic agent may have surface resistance of about 10¹⁰ Ω/sq or less.

The ink composition according to one or more embodiments of the present disclosure may include the first mill base including a carbon nanotube not to include a separate antistatic agent.

The leveling agent may be included in order to increase adhesion of the ink composition more by leveling so as to flatly and smoothly apply the ink composition. An acrylic compound, a silicon-based compound, and/or the like may be included alone or by mixing at least two kinds thereof as the leveling agent. For example, polyether-modified polydimethylsiloxane may be included, and a (meth)acryloyl group may be additively included in the polyether chain.

As a mixture of a lipophilic fluid and polysiloxane, the defoaming agent may serve to increase the exterior of the applied film by destroying a foam generated during application.

In one or more embodiments, substantially the same material may be used as the leveling agent and the defoaming agent. For example, polysiloxane may be used as the leveling agent and the defoaming agent.

In one or more embodiments, the additive in a range of about 0.2 wt % to about 4 wt % may be included with respect to the total content (e.g., amount) of 100% (e.g., based on a total of 100 wt %) of the ink composition.

The ink composition according to the present disclosure may further include a functional additive that is generally available or generally used in the art in a range not reducing an effect of the present disclosure. For example, examples of the usable functional additive may include an antioxidant, a lubricant, a surfactant, an adhesion promoter, a slip agent, a solvent, a wetting agent, a light stabilizer, a stain inhibitor, a softener, a thickener, a polymer and/or the like. These may be used alone, or at least two thereof may be mixed and used.

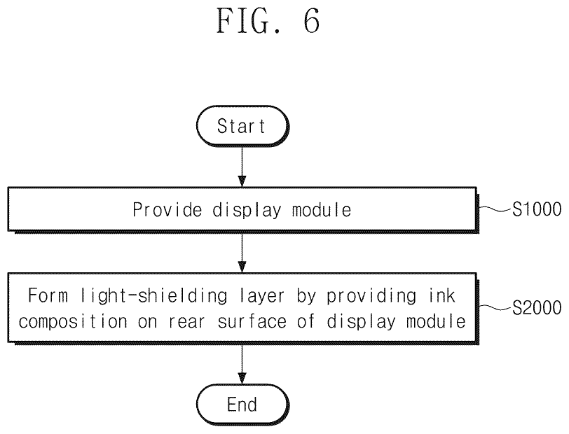

FIG. 6 is a flowchart illustrating a method for manufacturing an electronic device according to one or more embodiments of the present disclosure. FIG. 7 is a flowchart partially illustrating an operation of preparing an ink composition according to one or more embodiments of the present disclosure. FIG. 7 is a flowchart dividing and illustrating an operation of preparing a mill base in the operation of preparing an ink composition according to the present disclosure.

Referring to FIG. 6, a method for manufacturing an electronic device according to one or more embodiments may include an operation (S1000) of preparing a display module and an operation (S2000) of forming a light-shielding layer by providing an ink composition on a rear surface of the display module.

The method for manufacturing an electronic device according to one or more embodiments may further include an operation of preparing an ink composition. The light-shielding layer SL as illustrated in FIG. 2 and/or the like may be formed through an operation of forming a light-shielding layer by using the ink composition as described in one or more embodiments.

In the method for manufacturing an electronic device according to one or more embodiments, the operation of preparing an ink composition may include an operation of preparing a mill base. In one or more embodiments, the first mill base may be formed by mixing a carbon nanotube having an average aspect ratio of about 2000 to about 5000, a first dispersant, and at least one first (meth)acrylate monomer.

In one or more embodiments, an operation of preparing the first mill base may include an operation of preparing a mixture in which a carbon nanotube having an average aspect ratio of about 2400 to about 5000, a first dispersant, and at least one first (meth)acrylate monomer are mixed, and milling the mixture. In one or more embodiments, a ball milling method, a bead mill method, and/or the like may be used as the milling process.

The ink composition according to one or more embodiments of the present disclosure may include a pigment as a powder form or a separate mill base form.

In the method for manufacturing an electronic device according to one or more embodiments, the operation of preparing an ink composition may further include an operation of preparing a second mill base. In one or more embodiments, the second mill base may be formed by mixing a pigment, a second dispersant, and at least one second (meth)acrylate monomer.

In one or more embodiments, an operation of preparing the second mill base may include an operation of preparing a mixture in which a pigment, a second dispersant, and at least one second (meth)acrylate monomer are mixed, and milling the mixture. The pigment may be broken into particles having a small size through the milling process, and surfaces thereof may be modified by the dispersant. For example, the pigment may be broken into particles having a small size through the milling process, and substantially at the same time, surfaces thereof may be modified by the dispersant. The dispersant may be adsorbed to the surfaces of the broken particles. Accordingly, the pigment particles broken into smaller particles may not be agglomerated to each other and may be uniformly (e.g., substantially uniformly) dispersed in the composition due to the dispersant.

FIGS. 7A to 7K are cross-sectional views illustrating one or more operations of a method for manufacturing an electronic device according to one or more embodiments of the present disclosure. FIGS. 7A to 7K sequentially illustrate an operation of providing a light-shielding layer of the method for manufacturing an electronic device according to one or more embodiments of the present disclosure. The descriptions of the light-shielding layer according to one or more embodiments may be applied to the descriptions of the method for manufacturing an electronic device according to one or more embodiments. Hereinafter, if (e.g., when) the method for manufacturing an electronic device according to one or more embodiments is described with reference to FIGS. 7A to 7G, the same reference numerals or symbols may be imparted to substantially the same configuration or arrangement as that described herein, and more detailed description may not be provided.

Referring to FIG. 7A, the method for manufacturing an electronic device according to one or more embodiments may include an operation of providing the display module DM. The descriptions of the display module DM made in FIG. 2 and/or the like may be substantially identically applied for the display module DM as described with reference to FIGS. 7A to 7G.

The display module DM may include the base layer BS and an upper panel member DP-U arranged on the base layer BS. The upper panel member DP-U as illustrated in FIGS. 7A to 7G may refer to functional layers, except for the base layer BS, of the functional layers included in the display module DM illustrated in FIG. 5. For example, the upper panel member DP-U may include the circuit layer D-CL, the display element layer D-EL, the encapsulation layer TFE, the input sensor ISP, and the optical layer PL. However, configuration or arrangement of the upper panel member DP-U is not limited thereto, and at least one selected from among the functional layers included in the upper panel member DP-U may not be provided as necessary or desired.

The display module DM may include an upper surface and a lower surface opposite to each other with respect to the third direction DR3 corresponding to a direction in which light is emitted. The lower surface of the display module DM may be defined by the lower surface B-LF of the base layer BS.

The display module DM may further include a panel protection film PF arranged on the upper panel member DP-U. The panel protection film PF may be a layer arranged on an upper side of the display module DM to protect an upper surface of the display module DM. The panel protection film PF may entirely (e.g., substantially entirely) overlap the display module DM. The panel protection film PF may include a polymer material. For example, the panel protection film PF may be a polyimide film and/or a polyethylene terephthalate film. However, this is an example, and a material of the panel protection film PF is not limited thereto.

In the method for manufacturing an electronic device according to one or more embodiments, the display module DM may be provided in a state in which an acid-resistant film IF is adhered onto the upper surface of the display module DM. For example, as illustrated in FIG. 7A, the acid-resistant film IF may be adhered onto the upper surface of the display module DM. The acid-resistant film IF may be adhered onto the panel protection film PF.

The acid-resistant film IF may function to prevent the display module DM from being damaged (or reduce a degree to or occurrence of which the display module DM is damaged) by etchant in an operation of etching the base layer to be described herein. In the operation of etching the base layer, if (e.g., when) an upper portion of the display module DM is exposed to the etchant, the functional layers included in the display module DM may be damaged. The display module DM may be prevented from being damaged (or a degree to or occurrence of which the display module DM is damaged may be reduced) by the etchant by adhering the acid-resistant film IF to the upper portion of the display module DM before an etching process. However, embodiments of the present disclosure are not limited thereto, and in the method for manufacturing an electronic device according to one or more embodiments, if (e.g., when) the operation of etching the base layer is not provided, the display module DM may be provided in a state in which the acid-resistant film IF is not adhered.

The acid-resistant film IF may be performed of a transparent (e.g., substantially transparent) resin material, but embodiments of the present disclosure are not limited thereto. As long as not being melted by the etchant, the resin material of the acid-resistant film IF is not limited and may be polyester, polyester sulfone, triacetylcellulose, cycloolefin polymers, and/or the like.

Referring to FIGS. 7B and 7C, the method for manufacturing an electronic device according to one or more embodiments may further include an operation of etching a lower surface of the base layer before the operation of forming a light-shielding layer.

The base layer BS may include an upper surface B-UF and a lower surface B-LF opposite to each other with respect to the third direction DR3, which is a thickness direction. The upper surface B-UF of the base layer BS may be a surface adjacent to the upper panel member DP-U. The lower surface B-LF of the base layer BS may be a surface opposite to the upper surface B-UF of the base layer BS and spaced and/or apart (e.g., spaced apart or separated) from the upper panel member DP-U.

As illustrated in FIG. 7B, an etchant ES may be provided to the lower surface B-LF of the base layer BS. The etchant ES may etch the lower surface B-LF of the base layer BS. For example, the base layer BS may be partially etched by the etchant ES. In the upper surface B-UF and the lower surface B-LF of the base layer BS, the lower surface B-LF exposed to the outside may be in contact with the etchant ES and may be etched. In one or more embodiments, the upper panel member DP-U arranged on the upper side of the base layer BS may be protected by the acid-resistant film IF to be prevented from being damaged (or to reduce a degree or occurrence of being damaged) if (e.g., when) being exposed to the etchant ES. The acid-resistant film IF may be removed from the display module DM after the operation of etching the lower surface B-LF of the base layer BS.

As long as being capable of etching the base layer, the etchant is not limited and, for example, may include at least one of hydrofluoric acid, hydrochloric acid, or ammonium fluoride.

A thickness of the base layer BS may be reduced through the operation of etching the lower surface B-LF of the base layer BS. As illustrated in FIGS. 7B and 7C, a thickness d2 of the base layer BS after the etching process may be smaller than a thickness d1 of the base layer BS before the etching process. For example, the thickness d1 of the base layer BS before the etching process may be about 0.5 mm, and the thickness d2 of the base layer BS after the etching process may be about 0.2 mm, but embodiments of the present disclosure are not limited thereto.

Referring to FIGS. 7D to 7K, the method for manufacturing an electronic device according to one or more embodiments may include an operation of forming a light-shielding layer on the rear surface of the base layer.

The operation of forming a light-shielding layer according to one or more embodiments may include an operation of forming a preliminary light-shielding layer by providing the ink composition on the rear surface of the display module and an operation of photocuring the preliminary light-shielding layer.

Referring to FIG. 7D, an operation of turning the display module upside down may be performed before the operation of providing the ink composition. In a state in which the acid-resistant film IF (see FIG. 7C) is removed after the etching process, the display module DM may be turned upside down such that the lower surface B-LF of the base layer BS faces upward. In a state in which the display module DM is turned upside down, the upper panel member DP-U and the panel protection film PF may be arranged below the base layer BS. In a state in which the display module DM is turned upside down, the upper surface B-UF of the base layer BS may face downward, and the lower surface B-LF of the base layer BS may face upward, which is the third direction DR3.

After the display module DM is turned upside down, the ink composition IK may be provided on the lower surface B-LF of the base layer BS. The base layer BS may serve as a base material to apply the ink composition IK being a liquid phase. The ink composition IK may be provided on the lower surface B-LF of the base layer BS in a liquid phase form before curing. The ink composition IK may be directly provided to the lower surface B-LF of the base layer BS.

In one or more embodiments, the operation of providing the ink composition IK may be performed in a screen printing process. Hereinafter, an operation of providing the ink composition IK in the screen printing process will be described with reference to FIGS. 7E to 7K.

Referring to FIG. 7E, a screen mask SCM may include a printing region PR and a non-printing region NPR, and the ink composition IK may be provided on the non-printing region NPR of the screen mask SCM. Because the printing region PR has a mesh structure, the ink composition may pass through the printing region PR. The ink composition may pass through an opening of the mesh in a direction of the lower surface B-LF of the base layer BS to be printed on the lower surface B-LF of the base layer BS. The non-printing region NPR may have a structure in which the ink composition is blocked.

Because the ink composition IK according to one or more embodiments of the present disclosure has the configurations or arrangements as described herein, the ink composition IK staying on the non-printing region NPR may be prevented from unnecessarily or substantially flowing over the printing region PR and the lower surface B-LF of the base layer BS (or a degree to or occurrence of which the ink composition IK staying on the non-printing region NPR unnecessarily or substantially flows over the printing region PR and the lower surface B-LF of the base layer BS may be reduced). As a result, a stamping and smearing defect on one end of the light-shielding layer SL may be prevented (or a degree or occurrence of a stamping and smearing defect on one end of the light-shielding layer SL may be reduced).

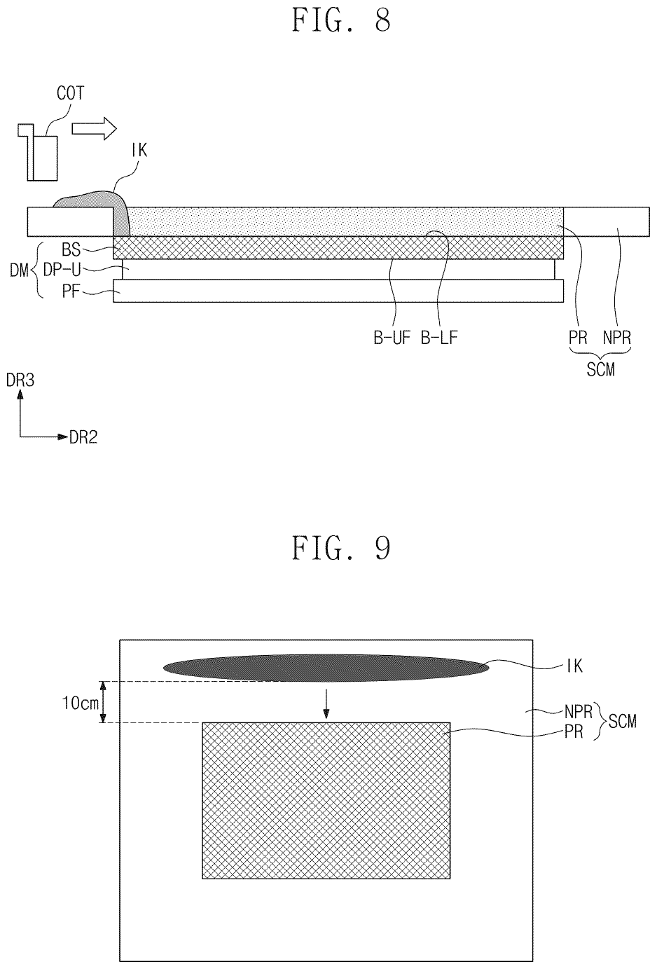

FIG. 8 is a diagram illustrating a limitation generated when an ink composition according to Comparative Example is utilized. Referring to FIG. 8, if (e.g., when) the ink composition has great or suitable flowability, the ink composition provided to the non-printing region NPR may unnecessarily or substantially flow onto the printing region PR and the lower surface B-LF of the base layer BS. Accordingly, the ink composition may be excessively or substantially loaded on an end part adjacent to the non-printing region NPR, and then the stamping and smearing defect caused by pressure may occur in a region in which the ink composition is excessively or substantially loaded in a printing process by using a squeegee SQG.

Referring to FIGS. 7E and 7F, a coater COT may be to load the ink composition IK on the non-printing region NPR in the printing region PR. For example, the coater COT may be to move in the second direction DR2 so that (e.g., such that) the ink composition IK may be loaded in the printing region PR.

Referring to FIGS. 7G and 7H, the squeegee SQG may be to press the printing region PR to print the ink composition IK on the base layer BS. For example, the squeegee SQG may be to press the printing region PR by moving in the first direction DR1, and thus to print the ink composition IK loaded in the printing region PR on the lower surface B-LF of the base layer BS.

Referring to FIGS. 71 and 7J, thereafter, a light source LL to cure may be provided to a preliminary light-shielding layer P-SL provided in a set or predetermined thickness by applying the ink composition IK. For example, the light source LL may be to emit an ultraviolet ray. However, embodiments of the present disclosure are not limited thereto. The light source LL may be provided in the entire region of the preliminary light-shielding layer P-SL. The preliminary light-shielding layer P-SL may be cured to finally form the light-shielding layer SL as illustrated in FIG. 7J.

The light-shielding layer SL formed in the process as illustrated in FIGS. 7A to 7K may be applied to the electronic device EA (see FIG. 2) as described herein in a form of being adhered to the rear surface of the display module DM. The display module DM and the light-shielding layer SL manufactured in the process illustrated in FIGS. 7A to 7K may be applied to the electronic device EA (see FIG. 2) according to one or more embodiments so as to have the disposition structure as illustrated in FIG. 2 and/or the like as described in one or more embodiments.

Hereinafter, a display device including an ink composition according to one or more embodiments and a light-shielding layer formed therefrom will be described in more detail through Examples and Comparative Examples. However, Examples and Comparative Examples are one example to describe the present disclosure in more detail, and embodiments of the present disclosure are not limited by Examples and Comparative Examples.

### Preparation of Ink Composition

### 1. EXAMPLE

### (1) Example 1

A single-walled carbon nanotube (SWCNT) having an average aspect ratio of about 2500 and a polyester-based dispersant (BYK-2152 from BYK) were prepared. 1,6-Hexanediol diacrylate was prepared as the first (meth)acrylate monomer, and pentaerythritol tetraacrylate was prepared as the (meth)acrylate monomer and the photopolymerization monomer. Also, carbon black powder was prepared as the pigment, a urethane acrylate oligomers having a weight average molecular weight in a range of about 5000 g/mol to about 10000 g/mol was prepared as the base resin, and an acetophenone-based photo initiator (irgacure 907) and a photo sensitizer were prepared as the photo initiator. Also, a polyester-based dispersant (BYK-2152 from BYK) was prepared as the dispersant, an amino silane-based coupling agent was prepared as the coupling agent, and polysiloxane (BYK-333 from BYK) was prepared as the leveling agent and the defoaming agent.

First, the single-walled carbon nanotube having an average aspect ratio of about 2500, the dispersant, 1,6-hexanediol diacrylate, and pentaerythritol tetraacrylate were put in a bead milling device and stirred to manufacture the first mill base.

The carbon black powder, the dispersant, 6-hexanediol diacrylate, and pentaerythritol tetraacrylate were put in the bead milling device and stirred for about 40 minutes to manufacture the second mill base.

The photopolymerization monomer and the photo initiator were mixed first and stirred, and the manufactured second mill base composition was put thereinto and stirred. Thereafter, the first mill base composition was additionally put and stirred. Thereafter, the mixture was subjected to a three-roll milling process at least three times to ensure that the ingredients were evenly (e.g., substantially evenly) mixed, and then the mixture was filtered to remove an impurity. Then, a diameter of the filter was in a range of about 30 μm to about 50 μm. Thereafter, the additives, such as the leveling agent, the defoaming agent, and the coupling agent, were additionally mixed and stirred to manufacture the ink composition.

### (2) Example 2

Except that the single-walled carbon nanotube (SWCNT) having an average aspect ratio of about 5000 instead of the single-walled carbon nanotube (SWCNT) having an average aspect ratio of about 2500 was used, the first mill base was prepared in substantially the same method as Example 1. Thereafter, the ink composition was manufactured in substantially the same method as Example 1 by using the first mill base and the second mill base.

### 2. COMPARATIVE EXAMPLE

### (1) Comparative Example 1

The second mill base was manufactured in substantially the same method as Example 1. The photopolymerization monomer and the photo initiator were mixed first and stirred, and the manufactured second mill base composition was put thereinto and stirred. Thereafter, the single-walled carbon nanotube (SWCNT) having an average aspect ratio of about 2500 was additionally put and stirred. Thereafter, the mixture was subjected to a three-roll milling process at least three times to ensure that the ingredients were evenly (e.g., substantially evenly) mixed, and then the mixture was filtered to remove an impurity. Then, a diameter of the filter was in a range of about 30 μm to about 50 μm. Thereafter, the additives, such as the leveling agent, the defoaming agent, and the coupling agent, were additionally mixed and stirred to manufacture the ink composition.

For example, except that the carbon nanotube instead of the first mill base was directly added, the ink composition was manufactured in substantially the same method as Example 1. The ink composition was manufactured such that the content (e.g., amount) of the carbon black was about 1.5 wt % with respect to the total weight (e.g., based on a total of 100 wt %) of the ink composition. For example, the content (e.g., amount) of the carbon black in the second mill base was about 15 wt %, and the content (e.g., amount) of the second mill base in the ink composition was about 10 wt %.

### (2) Comparative Example 2

Except for increasing the content (e.g., amount) of the carbon black power during manufacturing the second mill base, the ink composition was manufactured in substantially the same method as Comparative Example 1. The ink composition was manufactured such that the content (e.g., amount) of the carbon black was about 1.7 wt % with respect to the total weight (e.g., based on a total of 100 wt %) of the ink composition. For example, the content (e.g., amount) of the carbon black in the second mill base was about 15 wt %, and the content (e.g., amount) of the second mill base in the ink composition was about 11.3 wt %.

### (3) Comparative Example 3

Except for increasing the content (e.g., amount) of the carbon black power during manufacturing the second mill base, the ink composition was manufactured in substantially the same method as Comparative Example 1. The ink composition was manufactured such that the content (e.g., amount) of the carbon black was about 2.0 wt % with respect to the total weight (e.g., based on a total of 100 wt %) of the ink composition. For example, the content (e.g., amount) of the carbon black in the second mill base was about 15 wt %, and the content (e.g., amount) of the second mill base in the ink composition was about 13.3 wt %.

### (4) Comparative Example 4

Except for increasing stirring time to about 80 minutes during manufacturing the second mill base, the ink composition was manufactured in substantially the same method as Comparative Example 1. For example, the stirring time during manufacturing the second mill base was increased about twice longer than Comparative Example 1.

### (5) Comparative Example 5

Except for reducing the content (e.g., amount) of the dispersant to a half during manufacturing the second mill base, the ink composition was manufactured in substantially the same method as Comparative Example 1. For example, the second mill base was manufactured by using the carbon black powder of about 15 wt %, the (meth)acrylate monomer of about 82.5 wt % and the polyester dispersant of about 2.5 wt %.

### (6) Comparative Example 6

The single-walled carbon nanotube powder having an average aspect ratio of about 2500 was prepared instead of the first mill base. The carbon black powder was prepared instead of the second mill base as the pigment.

The pigment, the base resin, the photopolymerization monomer, the photo initiator, and the carbon nanotube were mixed and stirred. Thereafter, the mixture was subjected to a three-roll milling process at least three times to ensure that the ingredients were evenly (e.g., substantially evenly) mixed, and then the mixture was filtered to remove an impurity. Then, a diameter of the filter was in a range of about 30 μm to about 50 μm. Thereafter, the additives, such as the leveling agent, the defoaming agent, and the coupling agent, were additionally mixed and stirred for specific (e.g., set or predetermined) time to manufacture the ink composition.

### (7) Comparative Example 7

The amide ester-based thickener (RHEOBYK-7411 from BYK) was prepared as an organic thickener. Except for adding the organic thickener of about 1 wt % with respect to the total weight (e.g., based on a total of 100 wt %) of the ink composition during adding the second mill base to the mixture of the photopolymerization monomer and the photo initiator, the ink composition was manufactured in substantially the same method as Comparative Example 1.

### (8) Comparative Example 8

The polyamide-based thickener (RHEOBYK-7405 from BYK) was prepared as an organic thickener. Except for adding the organic thickener of about 1 wt % with respect to the total weight (e.g., based on a total of 100 wt %) of the ink composition during adding the second mill base to the mixture of the photopolymerization monomer and the photo initiator, the ink composition was manufactured in substantially the same method as Comparative Example 1.

### (9) Comparative Example 9

Except that the single-walled carbon nanotube (SWCNT) having an average aspect ratio of about 2000 instead of the single-walled carbon nanotube (SWCNT) having an average aspect ratio of about 2500 was used, the first mill base was prepared in substantially the same method as Example 1. Thereafter, the ink composition was manufactured in substantially the same method as Example 1 by using the first mill base and the second mill base.

### (10) Comparative Example 10

Except that the single-walled carbon nanotube (SWCNT) having an average aspect ratio of about 10000 instead of the single-walled carbon nanotube (SWCNT) having an average aspect ratio of about 2500 was used, the first mill base was prepared in substantially the same method as Example 1. Thereafter, the ink composition was manufactured in substantially the same method as Example 1 by using the first mill base and the second mill base.

The carbon black mill base (the second mill base) used in the ink composition of Examples 1 and 2 and Comparative Examples 1 to 5 and 7 to 10 includes the carbon black powder of about 15 wt %, the (meth)acrylate monomer of about 80 wt %, and the ester-based dispersant of about 5 wt %.

The CNT mill base (the first mill base) used in the ink composition of Examples and Comparative Examples includes the carbon nanotube of about 15 wt %, the (meth)acrylate monomer of about 83 wt %, and the ester-based dispersant of about 2 wt %.

The compositional ratio of the ink composition according to Examples and Comparative Examples are shown in Table 1. Table 1 shows the content (e.g., amount) of each component in the ink composition in weight percent (wt %). The item, “the rest” in Table 1 refers to the total weight percent (wt %) of the coupling agent (about 1 wt %), the leveling agent (about 0.5 wt %), and the defoaming agent (about 0.5 wt %).

TABLE 1

| | | | Carbon | | | | | |
|---|---|---|---|---|---|---|---|---|
| | | Carbon | black | | CNT | | | |
| | Base | black | mill | CNT | mill | Photopolymerization | Photo | The |
| Classification | resin | powder | base | powder | base | monomer | initiator | rest |
| Example 1 | 38 | — | 10 | — | 10 | 30 | 10 | 2 |
| Example 2 | 38 | — | 10 | — | 10 | 30 | 10 | 2 |
| Comparative | 46.5 | — | 10 | 1.5 | | 30 | 10 | 2 |
| Example 1 | | | | | | | | |
| Comparative | 45.2 | — | 11.3 | 1.5 | — | 30 | 10 | 2 |
| Example 2 | | | | | | | | |
| Comparative | 43.2 | — | 13.3 | 1.5 | — | 30 | 10 | 2 |
| Example 3 | | | | | | | | |
| Comparative | 46.5 | — | 10 | 1.5 | — | 30 | 10 | 2 |
| Example 4 | | | | | | | | |
| Comparative | 46.5 | — | 10 | 1.5 | — | 30 | 10 | 2 |
| Example 5 | | | | | | | | |
| Comparative | 55.0 | 1.5 | — | 1.5 | — | 30 | 10 | 2 |
| Example 6 | | | | | | | | |
| Comparative | 45.5 | — | 10 | 1.5 | — | 30 | 10 | 3 |
| Example 7 | | | | | | | | |
| Comparative | 45.5 | — | 10 | 1.5 | — | 30 | 10 | 3 |
| Example 8 | | | | | | | | |
| Comparative | 38 | — | 10 | — | 10 | 30 | 10 | 2 |
| Example 9 | | | | | | | | |
| Comparative | 38 | — | 10 | — | 10 | 30 | 10 | 2 |
| Example 10 | | | | | | | | |

### Evaluation of Properties of the Ink Composition and the Light-Shielding Layer

The properties of the ink compositions according to Examples and Comparative Examples were evaluated in the following methods, and then the results are shown with the main components of each of Examples and Comparative Examples in Table 2.

### 1. Thixotropic Index (T.I)

Viscosities at a low shear rate (about 0.5 rpm) and a high shear rate (about 5 rpm) were measured according to an ASTM D2196 method, and the viscosity at the low shear rate divided by the viscosity at the high shear rate was calculated as T.I. Each T.I is shown in Table 2.

### 2. Flowability

FIG. 9 is a diagram illustrating a method for evaluating flowability. Referring to FIG. 9, the ink composition IK according to Examples and Comparative Examples was ejected onto the non-printing region NPR of the screen mask SCM. Thereafter, time (t) which it took for the ink composition IK to move about 10 cm toward the printing region PR was measured, and is shown in Table 2.

### 3. Smearing Distance

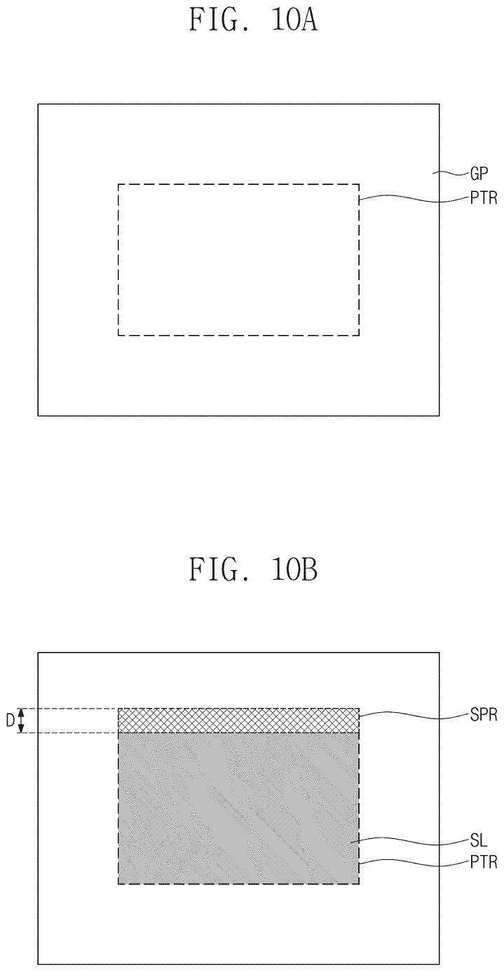

FIGS. 10A and 10B are diagrams illustrating a method for evaluating a smearing distance of a light-shielding layer. As in FIG. 10A, the light-shielding layer was formed by screen-printing the ink composition according to Examples and Comparative Examples on a target printing region PR of a glass substrate GP. Thereafter, as in FIG. 10B, it was confirmed whether or not the light-shielding layer SL was formed outside the target printing region PTR, and the region was defined as a smearing region SPR. A maximum distance D from the target printing region PTR to the smearing region SPR was measured and is shown in Table 2.

TABLE 2

| | | | | | Time for | |
|---|---|---|---|---|---|---|
| | | Flow | | | moving | Smearing |
| | | prevention | | | 10 cm (t) | distance |
| Classification | Pigment | agent | Thickener | T.I.* | (min) | D(um) |
| Example 1 | CB M/B | CNT | — | 1.9 | t > 30 | D = 0 |
| | | M/B(AR2,500) | | | | |
| Example 2 | CB M/B | CNT | — | 2.2 | t > 30 | D = 0 |
| | | M/B(AR5,000) | | | | |
| Comparative | CB M/B(CB | CNT | — | 1.3 | t > 30 | D > 400 |
| Example 1 | 1.5%) | | | | | um |
| Comparative | CB M/B(CB | CNT | — | 1.3 | t ≤ 5 | D > 400 |
| Example 2 | 1.7%) | | | | | um |
| Comparative | CB M/B(CB | CNT | — | 1.3 | t ≤ 5 | D > 400 |
| Example 3 | 2.0%) | | | | | um |
| Comparative | CB | CNT | — | 1.3 | t ≤ 5 | D > 400 |
| Example 4 | M/B(Dispersion | | | | | um |
| | time twice) | | | | | |
| Comparative | CB M/B(A half | CNT | — | 1.3 | t ≤ 5 | D > 400 |
| Example 5 | of dispersant | | | | | um |
| | content (e.g., | | | | | |
| | amount)) | | | | | |
| Comparative | CB | CNT | — | 1.3 | t ≤ 5 | D > 400 |
| Example 6 | | | | | | um |
| Comparative | CB M/B | CNT | Organic | 1.3 | t ≤ 5 | D > 400 |
| Example 7 | | | thickener#1 | | | um |
| Comparative | CB M/B | CNT | Organic | 1.3 | t ≤ 5 | D > 400 |
| Example 8 | | | thickener#2 | | | um |
| Comparative | CB M/B | CNT M/B | — | 1.6 | 5 < | 300 um < |
| Example 9 | | (AR2,000) | | | t ≤ 10 | D ≤ 400 |
| | | | | | | um |
| Comparative | CB M/B | CNT | — | 3.6 | t > 30 | — |
| Example 10 | | M/B(AR10,000) | | | | |

CB: Carbon black powder
CNT: Carbon nanotube powder having an average aspect ratio of about 2500
CB M/B: Mill base including carbon black
CNT M/B(AR2,000): Mill base including carbon nanotube having an average aspect ratio of about 2000
CNT M/B(AR2,500): Mill base including carbon nanotube having an average aspect ratio of about 2500
CNT M/B(AR5,000): Mill base including carbon nanotube having an average aspect ratio of about 5000
CNT M/B(AR10,000): Mill base including carbon nanotube having an average aspect ratio of about 10000
Organic thickener#1: RHEOBYK-7411 from BYK
Organic thickener#2: RHEOBYK-7405 from BYK

Referring to Table 2, the ink composition according to Examples of the present disclosure has the T.I in a range of about 1.9 to about 2,2 by including the carbon nanotube (CNT) having an average aspect ratio of about 2000 to about 5000 in a mill base form. As a result, it may be confirmed that flowability is suppressed or reduced so that (e.g., such that) it takes about 30 minutes or longer to move about 10 cm, and so that (e.g., such that) smearing does not occur on the panel. Accordingly, even when the ink composition according to Examples of the present disclosure is ejected onto the non-printing region of the screen mask and time elapses, a defect caused by flowability may be prevented (or a degree or occurrence of a defect caused by flowability may be reduced).

In one or more embodiments, referring to Comparative Examples 1 to 8, it may be confirmed that even when another component (carbon black) is added in the mill base form, or a separate thickener is added in a case in which the carbon nanotube (CNT) is added in a powder form, flowability is not suppressed or reduced, and thus smearing occurs in the light-shielding layer. For example, when the ink composition according to Comparative Examples is ejected onto the non-printing region of the screen mask and time elapses, the ink composition according to Comparative Examples may flow into the printing region, and thus stamping and smearing may occur in the light-shielding layer in the following printing process.

In one or more embodiments, referring to Comparative Example 9, when the average aspect ratio of the carbon nanotube in the mill base is smaller than about 2000, an effect of suppressing or reducing flowability may be very tiny or unsubstantial, and thus stamping and smearing may occur in the light-shielding layer.

In one or more embodiments, referring to Comparative Example 10, it may be confirmed that when the carbon nanotube in the mill base has an average aspect ratio greater than about 10000, flowability is excessively or substantially suppressed or reduced. Because the flowability is excessively or substantially suppressed or reduced, the ink composition may smoothly pass through the screen mask, and as a result, the light-shielding layer is not normally formed on the glass substrate.

Thereafter, in the ink composition according to Examples, in order to confirm whether or not, when the carbon nanotube is put in a powder form, adhesion maintenance ability and application uniformity are affected, storage stability and application uniformity of Examples 1 and 2 and Comparative Example 1 were evaluated and are shown in Table 3.

### 4. Storage Stability

The ink composition according to Examples 1 and 2 and Comparative 1 were manufactured and left at room temperature for about 16 hours. Thereafter, adhesion was measured as follows, and whether or not adhesion strength was maintained to 5B are shown in Table 3.

### Measuring Adhesion

The adhesion was measured using an ASTM D3359 method. For example, a thin film formed on the substrate is cut in a checkerboard, then a tape is applied onto the thin film and the tape is removed to measure the adhesion of the thin film. If (e.g., when) the thin film sticks to the tape well or suitably to reveal the substrate after removing the tape, the thin film is referred to as showing bad adhesion, and if (e.g., when) the film remains on the substrate after removing the tape, the thin film is referred to as showing excellent or suitable adhesion.

With respect to a cutting area formed on the thin film in the checkerboard form, a case in which the thin film is not removed so that (e.g., such that) all is left is referred to as 5B, a case in which the checkerboard area of about 5% or less is pulled off is referred to as 4B, a case in which the checkerboard area of about 5% to about 15% is pulled off is referred to as 3B, a case in which the checkerboard area of about 15% to about 35% is pulled off is referred to as 2B, a case in which the checkerboard area of about 35% to about 63% is pulled off is referred to as 1B, and a case in which the checkerboard area of about 65% or more is pulled off is referred to as 0B. According to the foregoing classification, 5B refers to excellent or suitable adhesion, and 0B refers to bad adhesion.

### 5. Application Uniformity

The light-shielding layer was formed by performing screen printing on a lower surface of the base layer (glass substrate) using the ink composition according to Examples 1 and 2 and Comparative Example 1. Thereafter, whether or not there is each of a stain and a pin-hole defect observed in the light-shielding layer by a microscope was confirmed and is shown in Table 3.

TABLE 3

| | | | Whether | | |
|---|---|---|---|---|---|
| | | | adhesion of 5B is | Application | |
| | | Flowing | maintained or | uniformity | |
| | | prevention mill | not (Storage | Pin-hole | |
| Classification | Pigment | base | stability) | defect | Stain |
| Example 1 | CB M/B | CNT | ◯ | X | X |
| | | M/B(AR2,500) | | | |
| Example 2 | CB M/B | CNT | ◯ | X | X |
| | | M/B(AR5,000) | | | |
| Comparative | CB M/B | CNT | ◯ | X | X |
| Example 1 | | | | | |

Referring to Table 3, it may be confirmed that all of the ink compositions according to Examples 1 and 2 and Comparative Example 1 have excellent or suitable storage stability and application uniformity. Through this, it may be confirmed that putting the carbon nanotube in the powder form does not affect adhesion maintenance ability and application uniformity.

Because the carbon black mill base improves or enhances storage stability and application uniformity in the ink composition, the carbon nanotube mill base suppresses or reduces flowability of the ink composition as described herein, it is confirmed that when the carbon black mill base and the carbon nanotube mill base are used together, properties of the ink composition are improved or enhanced more, and thus defect rates of the light-shielding layer and the electronic device including the same may be reduced.

A light-shielding layer formed through an ink composition according to one or more embodiments of the present disclosure may exhibit excellent or suitable light-shielding properties, durability, and adhesion. In one or more embodiments, an electronic device including the light-shielding layer formed through the ink composition according to one or more embodiments may have improved or enhanced durability and reliability.

For example, one or more embodiment of the present disclosure provide an ink composition, an electronic device including a light-shielding layer formed from the ink composition, and a method for manufacturing the electronic device, each offering a combination of improved or enhanced dispersion stability, controlled flowability, and excellent or suitable adhesion. By incorporating a first mill base containing a carbon nanotube having an average aspect ratio of about 2000 to about 5000, a first dispersant, and at least one (meth)acrylate monomer, the ink composition achieves uniform (e.g., substantially uniform) dispersion and enhanced processability without the need for solvents. If (e.g., when) combined with a second mill base containing a pigment, the composition further improves or enhances storage stability and application uniformity. These synergistic effects enable the formation of a light-shielding layer exhibiting superior optical properties, durability, and adhesion, thereby reducing defect rates and enhancing the reliability of electronic devices, such as display panels. Furthermore, the disclosed method is compatible with scalable processes, including screen printing and photocuring, making it suitable for high-volume manufacturing of next-generation electronic devices.

The light-emitting element, the display apparatus/device, the electronic apparatus/device, the manufacturing apparatuses thereof, or any other relevant apparatuses/devices or components according to one or more embodiments of the present disclosure described herein may be implemented utilizing any suitable hardware, firmware (e.g., an application-specific integrated circuit), software, or a combination of software, firmware, and hardware. For example, the one or more suitable components of the device may be formed on one integrated circuit (IC) chip or on separate IC chips. Further, the one or more suitable components of the device may be implemented on a flexible printed circuit film, a tape carrier package (TCP), a printed circuit board (PCB), or formed on one substrate. Further, the one or more suitable components of the device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

Also, unless otherwise specified, the following terms have the meanings provided below:

“Mill base” refers to an intermediate dispersion prepared by mixing solid particles (e.g., pigments or carbon nanotubes) with a dispersant and a liquid medium (e.g., monomer or resin) to achieve uniform (e.g., substantially uniform) particle distribution before incorporation into the final ink composition.

“Diameter” refers to the cross-sectional diameter of the carbon nanotube if (e.g., when) the cross-section is substantially circular, and refers to the length of the major axis if (e.g., when) the cross-section is non-circular.

“Aspect ratio” refers to the ratio of the average length to the average diameter of the carbon nanotube, as determined by measuring 50 randomly selected nanotubes using SEM or TEM images.

“(Meth)acrylate monomer” refers to a monomer including at least one acrylate or methacrylate functional group.

“Photo initiator” refers to a compound that initiates polymerization upon exposure to UV or visible light.

“Substantially free of solvent” refers to that no solvent is intentionally added, except for residual amounts present as impurities or by-products that do not materially affect the properties of the ink composition.

In the present disclosure, each suitable feature of the one or more embodiments of the disclosure may be combined or combined with each other, partially or entirely, and may be technically interlocked and operated in one or more suitable ways, and each embodiment may be implemented independently of each other or in conjunction with each other in any suitable manner unless otherwise stated or implied.

While certain embodiments of the present disclosure have been described and illustrated herein, a person having ordinary skill in the art to which the present disclosure pertains shall appreciate that there may be one or more suitable modifications and permutations of the present disclosure without departing from the spirit and scope of the present disclosure that are defined in the appended claims and equivalents thereof. Moreover, it shall be appreciated that the disclosed embodiments are not intended to restrict the aspects and features of the present disclosure thereto and that the technical ideas and aspects of the present disclosure are interpreted to be included within the scope of the appended claims and their equivalents.

What is claimed is:

1. An ink composition comprising:
a first mill base;
a base resin;
a pigment; and
a photo initiator,
wherein the first mill base comprises:
a carbon nanotube having an average aspect ratio of 2000 to 5000;
a first dispersant; and
at least one first (meth)acrylate monomer.

2. The ink composition as claimed in claim 1, wherein the carbon nanotube has an average diameter of 2 nm or less and an average length in a range of 5 μm to 10 μm.

3. The ink composition as claimed in claim 1, wherein the carbon nanotube comprises at least one of a single-walled carbon nanotube or a multi-walled carbon nanotube.

4. The ink composition as claimed in claim 1, wherein, based on a total of 100 wt % of the first mill base,
the carbon nanotube is in an amount of 5 wt % to 20 wt %,
the first dispersant is in an amount of 1 wt % to 10 wt %, and
the at least one first (meth)acrylate monomer is in an amount of 70 wt % to 85 wt %.

5. The ink composition as claimed in claim 1, wherein the pigment comprises at least one black pigment of carbon black, lactam black, aniline black, or perylene black.

6. The ink composition as claimed in claim 1, further comprising:
a photo polymerizable monomer having two or more polymerizable functional groups;
a coupling agent; and
an additive comprising at least one of an antistatic agent, a leveling agent, or a defoaming agent.

7. The ink composition as claimed in claim 6, further comprising a second mill base,
wherein the second mill base comprises:
the pigment;
a second dispersant; and
at least one second (meth)acrylate monomer.

8. The ink composition as claimed in claim 7, wherein, based on a total of 100 wt % of the ink composition,
the base resin is in an amount of 25 wt % to 60 wt %,
the photo initiator is in an amount of 5 wt % to 15 wt %,
the first mill base is in an amount of 1 wt % to 15 wt %,
the photo polymerizable monomer is in an amount of 25 wt % to 60 wt %,
the second mill base is in an amount of 5 wt % to 20 wt %,
the coupling agent is in an amount of 0.5 wt % to 3 wt %, and
the additive is in an amount of 0.2 wt % to 4 wt %.

9. The ink composition as claimed in claim 1, wherein the ink composition does not comprise a solvent.

10. The ink composition as claimed in claim 1, wherein the base resin comprises a polymer resin having a weight average molecular weight in a range of 5000 g/mol to 50000 g/mol.

11. An electronic device comprising:
a display module;
a light-shielding layer below the display module and formed of an ink composition; and
a housing accommodating the display module,
wherein the ink composition comprises:
a first mill base;
a base resin;
a pigment; and
a photo initiator, and
wherein the first mill base comprises:
a carbon nanotube having an average aspect ratio of 2000 to 5000;
a first dispersant; and
at least one first (meth)acrylate monomer.

12. The electronic device as claimed in claim 11, wherein the light-shielding layer has a thickness in a range of 9 μm to 16 μm.

13. The electronic device as claimed in claim 11, wherein the display module comprises:
a base layer; and
a display element layer on the base layer, the display element layer comprising a light-emitting element, and
wherein the light-shielding layer is directly below the base layer.

14. The electronic device as claimed in claim 11, wherein the light-shielding layer is a single layer formed from the ink composition.

15. A method comprising:
providing a display module; and
forming a light-shielding layer by providing an ink composition on a rear surface of the display module,
wherein the ink composition comprises:
a first mill base;
a base resin;
a pigment; and
a photo initiator,
wherein the first mill base comprises:
a carbon nanotube having an average aspect ratio of 2000 to 5000;
a first dispersant; and
at least one first (meth)acrylate monomer, and
wherein the method is a method for manufacturing an electronic device.

16. The method as claimed in claim 15, further comprising preparing the ink composition,
wherein the preparing of the ink composition comprises preparing a first mill base composition by mixing a carbon nanotube having an average aspect ratio of 2000 to 5000, a first dispersant, and the at least one first (meth)acrylate monomer.

17. The method as claimed in claim 15, wherein the forming of the light-shielding layer comprises:
forming a preliminary light-shielding layer by providing the ink composition on the rear surface of the display module; and
photocuring the preliminary light-shielding layer.

18. The method as claimed in claim 17, wherein the providing of the ink composition is performed by screen printing.

19. The method as claimed in claim 15, wherein the display module comprises:
a base layer; and
a display element layer on the base layer, the display element layer comprising a light-emitting element, and
wherein the light-shielding layer is directly formed below the base layer.

20. The method as claimed in claim 19, wherein:
the base layer comprises a glass substrate;
the method further comprises etching a lower surface of the base layer spaced from the display element layer, before the forming of the light-shielding layer; and
in the forming of the light-shielding layer, the ink composition is applied on the etched lower surface of the base layer.
